(19) United States
(12) Patent Application Publication
(10) Pub. No.: US 2007/0059945 A1
(43) Pub. Date: Mar. 15, 2007

(54) Atomic layer deposition with nitridation and oxidation

(76) Inventor: Nima Mohklesi, Los Gatos, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/224,630

(22) Filed: Sep. 12, 2005

(51) Int. Cl. H01L 21/31

(52) U.S. Cl. 438/778

(57) ABSTRACT

A dielectric layer is created for use with non-volatile memory and/or other devices. The dielectric layer is created using atomic layer deposition to deposit multiple components whose mole fractions change as a function of depth in the dielectric layer in order to create a rounded bottom of a conduction band profile for the dielectric layer. In one embodiment, after deposition of the precursors and a purge step, the atomic layer deposition cycle includes a nitridation step that is followed by or overlapped by an oxidation step.

### CROSS-REFERENCE TO RELATED APPLICATIONS

The following applications are cross-referenced and are incorporated by reference herein in their entirety:

U.S. patent application Ser. No. ______ [Attorney Docket No. SAND-01022US0], entitled “CREATING A DIELECTRIC LAYER USING ALD TO DEPOSIT MULTIPLE COMPONENTS,” inventor Nima Mokhlesi, filed the same day as the present application; and

U.S. patent application Ser. No. ______ [Attorney Docket No. SAND-01022US1], entitled “DIELECTRIC LAYER CREATED USING ALD TO DEPOSIT MULTIPLE COMPONENTS,” inventor Nima Mokhlesi, filed the same day as the present application.

### BACKGROUND OF THE INVENTION

1. Field of the Invention

The present invention relates to dielectric layers.

2. Description of the Related Art

Semiconductor memory devices have become more popular for use in various electronic devices. For example, non-volatile semiconductor memory is used in cellular telephones, digital cameras, personal digital assistants, mobile computing devices, non-mobile computing devices, and other devices. Electrical Erasable Programmable Read Only Memory (EEPROM) and flash memory are among the most popular non-volatile semiconductor memories.

Typical EEPROMs and flash memories utilize a memory cell with a floating gate that is provided above a channel region in a semiconductor substrate. The floating gate is separated from the channel region by a dielectric layer. For example, the channel region is positioned in a p-well between source and drain regions. A control gate is provided over and separated from the floating gate. The threshold voltage of the memory cell is controlled by the amount of excess charge that is retained on the floating gate. That is, the level of charge on the floating gate determines the minimum amount of voltage that must be applied to the control gate before the memory cell is turned on to permit conduction between its source and drain.

Some EEPROM and flash memory devices have a floating gate that is used to store two ranges of charges and, therefore, the memory cell can be programmed/erased between two states (e.g. a binary memory cell). A multi-bit or multi-state flash memory cell is implemented by identifying multiple, distinct threshold voltage ranges within a device. Each distinct threshold voltage range corresponds to predetermined values for the set of data bits. The specific relationship between the data programmed into the memory cell and the threshold voltage levels of the cell depends upon the data encoding scheme adopted for the cells. For example, U.S. Pat. No. 6,222,762 and U.S. patent application Ser. No. 10/461,244, “Tracking Cells For A Memory System,” filed on Jun. 13, 2003, both of which are incorporated herein by reference in their entirety, describe various data encoding schemes for multi-state flash memory cells. To achieve proper data storage for a multi-state cell, the multiple ranges of threshold voltage levels should be separated from each other by sufficient margin so that the level of the memory cell can be read, programmed or erased in an unambiguous manner.

When programming typical prior art EEPROM or flash memory devices, a program voltage is applied to the control gate and the bit line is grounded. Electrons from the channel are injected into the floating gate. When electrons accumulate in the floating gate, the floating gate becomes negatively charged and the threshold voltage of the memory cell as seen from the control gate is raised.

Typically, the program voltage (e.g., 12-20 volts) applied to the control gate is applied as a series of pulses. The magnitude of the pulses is increased with each successive pulse by a predetermined step size (e.g. 0.2 v). In the periods between the pulses, verify operations are carried out. That is, the programming level of each cell of a group of cells being programmed in parallel is read between each programming pulse to determine whether it is equal to or greater than each individual cell's targeted verify level to which it is being programmed. One means of verifying the programming is to test conduction at a specific compare point. The cells that are verified to be sufficiently programmed are locked out, for example, by raising the bit line voltage from 0 to Vdd just before the application of a programming pulse on those bit lines whose corresponding cells are to be inhibited from further programming in order to stop the programming process for those cells. The above described programming technique, and others, can be used in combination with various self boosting techniques, for example, as described in U.S. patent application Ser. No. 10/379,608, titled “Self Boosting Technique,” filed on Mar. 5, 2003, incorporated herein by reference in its entirety. Additionally, an efficient verify technique can be used, such as described in U.S. patent application Ser. No. 10/314,055, “Smart Verify for Multi-State Memories,” filed Dec. 5, 2002, incorporated herein by reference in its entirety.

Typical prior art memory cells are erased by raising the p-well to an erase voltage (e.g. 20 volts) and grounding the control gate. The source and drain are floating. Electrons are transferred from the floating gate to the p-well region and the threshold voltage is lowered.

Typically, the program and erase process described above is accomplished using electric field induced tunneling, also known as Fowler-Nordheim tunneling. While Fowler-Nordheim tunneling has worked well, and continues to work well, there is a desire to increase the speed of the program and erase processes, and to lower the voltages used to program and erase. However, it is preferable that an improvement in speed or magnitude of voltage is not made at an unreasonable loss of data retention time.

In “Resonant Fowler-Nordheim Tunneling through Layered Tunnel Barriers and its Possible Applications,” Alexander Korotkov and Konstantin Likharev, 1999 IEEE, 0-7803-5413-3/99 (hereinafter “Likharev I”); “Riding the Crest of a New Wave in Memory, NOVORAM: A new Concept for Fast, Bit-Addressable Nonvolatile Memory Based on Crested Barriers,” Konstantin and Likharev, Circuits and Devices, July 2000, p. 17 (hereinafter “Likharev II”); and U.S. Pat. No. 6,121,654, Sep. 19, 2000 “Memory device having a crested tunnel barrier” (hereinafter “the '654 patent”), it is suggested that charge injection may be sped up by using profiled (“crested”) tunnel barriers with a potential maximum in the middle. Likharev I and Likharev II specifically suggest using a tunnel barrier dielectric layer with a triangular shaped bottom of a conduction band profile. However, such a proposal is not optimal. For example, at the peak of the apex, there is a sudden transition which may set up for trapping. Furthermore, an author of Likharev I and Likharev II specifically suggests that such a triangular barrier may have fabrication issues. Similarly, the '654 patent proposes a tunnel barrier dielectric layer with a round shaped bottom of a conduction band profile; however, the '654 patent admits that such a barrier may be difficult to manufacture.

### SUMMARY OF THE INVENTION

A dielectric layer is disclosed that is created using atomic layer deposition to deposit multiple components whose mole fractions change as a function of depth in the dielectric layer in order to create a rounded bottom of a conduction band profile for the dielectric layer.

One embodiment includes creating said dielectric layer using atomic layer deposition to add a first component and a second component so that said dielectric layer gradually transitions from said first component to said second component and back to said first component.

One embodiment includes creating a first edge region using atomic layer deposition to add one or more layers of a first component and one or more layers of a second component, where the first edge region has a first conduction band bottom level. A center region is created using atomic layer deposition to add one or more layers of the first component and one or more layers of the second component. The center region has a second conduction band bottom level. A second edge region is created using atomic layer deposition to add one or more layers of the first component and one or more layers of the second component. The center region is between the first edge region and the second edge region. The second edge region has a third conduction band bottom level. The second conduction band bottom level is greater than the first conduction band bottom level and the third conduction band bottom level.

The processes described herein can be used to create a dielectric layer comprising a first type of component added by atomic layer deposition and a second first type of component added by atomic layer deposition. The first type of component and the second first type of component have varying mole fractions as a function of depth in the dielectric layer in order to create a rounded bottom of a conduction band profile for the dielectric layer.

In one embodiment, after deposition of one or more precursors and a purge step, the atomic layer deposition cycle includes a nitridation step that is followed by or overlapped by an oxidation step. One example implementation includes introducing a first set of one or more precursors into a chamber, introducing one or more nitriding agents into the chamber after introducing the first precursor, and introducing one or more oxidizing agents into the chamber. The nitriding agents are introduced during a first time period. The oxidizing agents are introduced during a second time period. The second time period is shorter than the first time period, starts after the first time period starts and/or includes a lower concentration than during the first time period.

The dielectric layer described above can be used with various types of flash memory devices, other types of non-volatile memory or other electronic devices.

### BRIEF DESCRIPTION OF THE DRAWINGS

FIGS. 1A, 1B, 2A, 2B, 2C and 2D are energy band diagrams for flash memory cells.

FIG. 3 is a flow chart describing one embodiment of a process for depositing one layer of HfO₂.

FIG. 4 is a flow chart describing one embodiment of a process for depositing one layer of Al₂O₃.

FIG. 5 is a flow chart describing one embodiment of a process for preparing regions of a dielectric.

FIG. 6 is a flow chart describing one embodiment of a process for preparing regions of a dielectric.

FIG. 7 is a flow chart describing one embodiment of a process for preparing regions of a dielectric.

FIGS. 8A-8D are flow charts describing examples of embodiments of processes for preparing the various regions of the steps of FIG. 7

FIG. 9 is a two-dimensional block diagram of one embodiment of a flash memory cell.

FIG. 10 is a two-dimensional block diagram of one embodiment of a flash memory cell.

FIG. 11 is a three dimensional drawing of portions of two NAND strings.

FIG. 12 is a flow chart describing one embodiment of the front end of a process for manufacturing the memory cell of FIG. 10.

FIGS. 13A-F depict the non-volatile memory device of FIG. 10 at various stages of the process described in FIG. 12.

FIGS. 14A, 14B, 14C and 14D are energy band diagrams for flash memory cells.

FIG. 15 is a block diagram of one example of a memory system that can be used to implement the present invention.

FIG. 16 illustrates an example of an organization of a memory array.

FIG. 17 is a flow chart describing one embodiment of a process for performing an ALD process.

FIG. 18 is a flow chart describing one embodiment of a process for performing an ALD process.

FIGS. 19A-C are graphs that illustrate co-injection processes.

FIG. 20 is a flow chart describing one embodiment of a process for creating a dielectric.

FIG. 21 is a block diagram of one embodiment of an ALD system.

FIG. 22 is an energy diagram.

FIG. 23 is a flowchart of one embodiment for performing an ALD process

### DETAILED DESCRIPTION

The invention is illustrated by way of example, and not by way of limitation, in the figures of the accompanying drawings in which like references indicate similar elements. It should be noted that references to an or one embodiment in this disclosure are not necessarily the same embodiment, and such references mean at least one.

In the following description, various aspects of the present invention will be described. However, it will be apparent to those skilled in the art that the present invention may be practiced with only some or all of the aspects of the present disclosure. For purposes of explanation, specific numbers, materials and configurations are set forth in order to provide a thorough understanding of the invention. However, it will be apparent to one skilled in the art that the present invention may be practiced without all of the specific details. In other instances, well known features are omitted or simplified in order not to obscure the present invention.

Various embodiments will be described as multiple discreet steps in turn, in a manner that is most helpful in understanding the present invention. However, the order of this description should not be construed as to imply that these operations are necessarily order dependent.

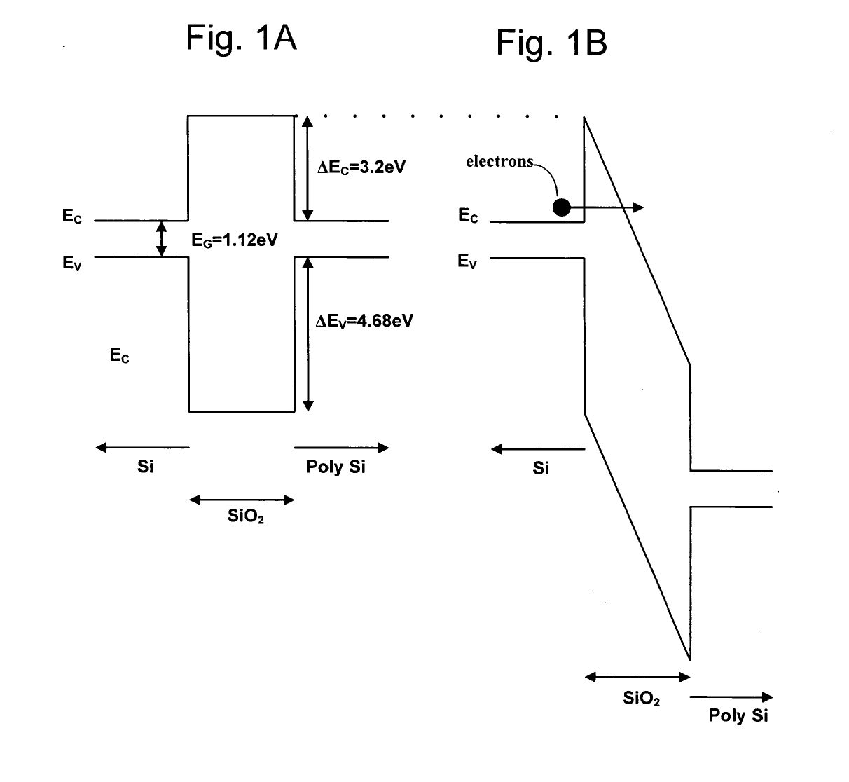

FIG. 1A depicts an energy band diagram for a Si/SiO₂/Poly Silicon structure with a 7.5 nm silicon oxide tunnel dielectric used in a flash memory device or other non-volatile storage device. The bottom of the conduction band is labeled as E_{c}, the top of the valance band is labeled as Eᵥ, ΔE_{C}=3.2 eV, ΔE_{V}=4.68 eV, and ΔE_{G}=1.12 eV, The energy band diagram of FIG. 1A depicts a rectangular bottom of the conduction band profile for the dielectric SiO₂. FIG. 1A shows three regions. The first region (labeled Si) is for the silicon substrate. The second region is for the dielectric SiO₂. The third region is for the polysilicon (Poly Si) floating gate. The bottom edge of the conduction band will be higher in the dielectric region than in the silicon and polysilicon regions.

When an electric field is applied to a device according to FIG. 1A, the conduction band and valance bands change as depicted in FIG. 1B. Although the width of the barrier is thinner, the height of the bottom of the conduction band still remains at the same level as if there were no electric field applied (see dotted line). Fowler Nordheim tunneling of electrons occurs under a high electric field of approximately 10 MV/cm, achieved with application of 7.5V across 7.5 nm of silicon oxide. The bottle-neck for current occurs at the triangular energy barrier at the cathode (Si substrate in the case shown in this figure). Direct tunneling through the triangular tunnel barrier at the cathode is referred to as Fowler Nordheim tunneling.

It would be desirable that the application of the electric field lower the height of the bottom of the conduction band. Thus, it is proposed to use a rounded bottom of a conduction band profile for a dielectric layer. This can be accomplished by using two or more components to create the dielectric layer.

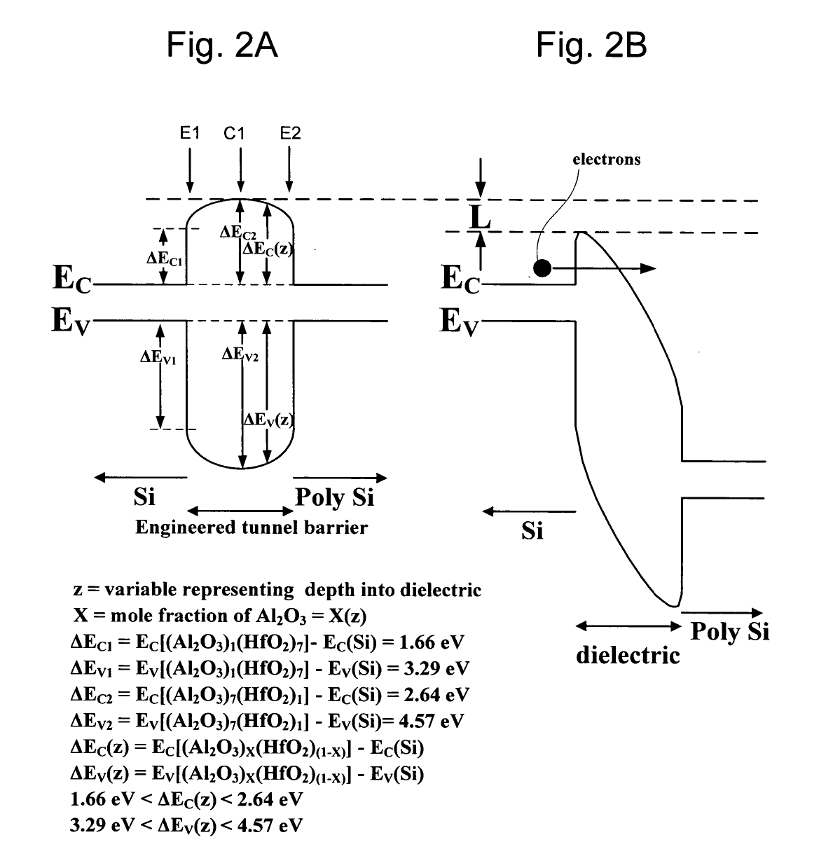

FIG. 2A depicts an energy band diagram for one embodiment of a tunnel dielectric layer that has a rounded bottom of a conduction band profile. The structure is a Si/smoothly crested barrier/PolySi Structure. The bottom of the conduction band profile is crested in that it has a peak in the interior of the shape and the edges are lower than the peak. As drawn, FIG. 2A roughly illustrates a material layer composed of mostly hafnium oxide at the two edges E1 and E2 (e.g., seven parts hafnium oxide and one part aluminum oxide), and mostly aluminum oxide at the center C1 (e.g., one part hafnium oxide and seven parts aluminum oxide), with a composition that gradually changes from mostly hafnium oxide to mostly aluminum oxide as a function of depth, z, into the dielectric traversed from either dielectric edge towards the center of the dielectric.

An electric field causes the bottom of the conduction band and top of the valance band to be altered as depicted in FIG. 2B. One feature is that the highest point on the bottom of the conduction band is now lower than when no electric field is applied, as labeled by arrow L. The application of a smaller voltage than that required for a uniform tunnel barrier (e.g. FIG. 1B) will result in electrons tunneling through this dielectric. The transition from non-conducting to conducting dielectric occurs over a significantly smaller voltage range in this dielectric as compared to a uniform dielectric such as SiO₂. This is because, in contrast to homogeneous dielectrics, the barrier height is being reduced here with the application of voltage between the two conductors that reside on opposite sides of the dielectric.

FIG. 2C depicts an energy band diagram for another embodiment of a crested tunnel dielectric layer that has a rounded bottom of a conduction band profile. The structure is a Si/smoothly crested barrier/PolySi Structure. As drawn, FIG. 2C roughly illustrates a material layer composed of hafnium oxide at the two edges (E10 and E20) and aluminum oxide at the center (C10), with a composition that gradually changes from hafnium oxide to aluminum oxide as a function of depth, z, into the dielectric traversed from either dielectric edge towards the center of the dielectric. An electric field causes the bottom of the conduction band and top of the valance band to be altered as depicted in FIG. 2D. The advantaged discussed above with respect to FIG. 2B also apply to FIG. 2D.

Atomic Layer Deposition (ALD) can be employed to deposit mixed multiple dielectrics to achieve such a rounded (or otherwise crested) bottom of a conduction band profile for the dielectric layer. Example of sets of dielectric materials that can be deposited using ALD include HfO₂ (hafnium oxide) and Al₂O₃ (aluminum oxide), hafnium oxide with silicon oxide, hafnium oxide with silicon dioxide, aluminum oxide with silicon oxide, as well as other sets of two or more materials.

ALD is a self-limiting chemisorption reaction. The basic sequence of ALD processing is composed of four steps. First, there is chemisorption of a first precursor on a substrate surface within an ALD chamber. Second, excess materials are purged out of the chamber using a purge gas, which leaves a monolayer of precursor absorbed on the substrate surface. Third, a second precursor is introduced into the chamber, which reacts with the adsorbate to form a monolayer. Fourth, un-reactive material or byproduct is purged out of the chamber by the purge gas. The cycle is then repeated to lay down additional layers. An example of a purge gas can be an inert gas. In some embodiments, the substrate (e.g., Si substrate) is first cleaned in a cleaning solution (e.g., 4% HF solution) to remove native oxide layers and blown free of particles before loading into the ALD chamber.

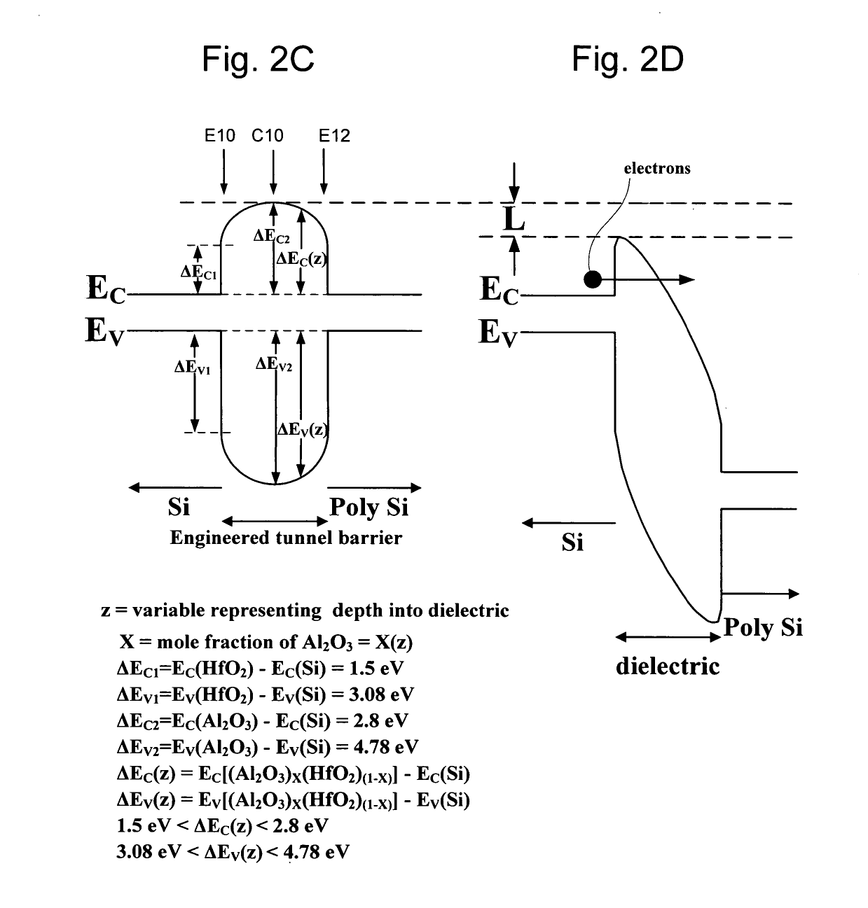

FIG. 3 is a flowchart describing one embodiment of the process for depositing one layer of HfO₂ using ALD. In step 102, a first precursor is inserted into the ALD chamber. One example of a suitable first precursor is HfCl₄. In one embodiment, step 102 is performed by having a gas carry the precursor. For example, an inert gas such as Argon could carry HfCl₄. In step 104, the ALD chamber is purged. In one embodiment, the ALD chamber is purged with an inert gas. In step 106, an oxidizing agent (the second precursor) is introduced into the chamber. Examples of suitable oxidizing agents include H₂O, O₃, other suitable oxidizing agents, or other suitable precursors. In step 108, the ALD chamber is purged; for example, using an inert gas.

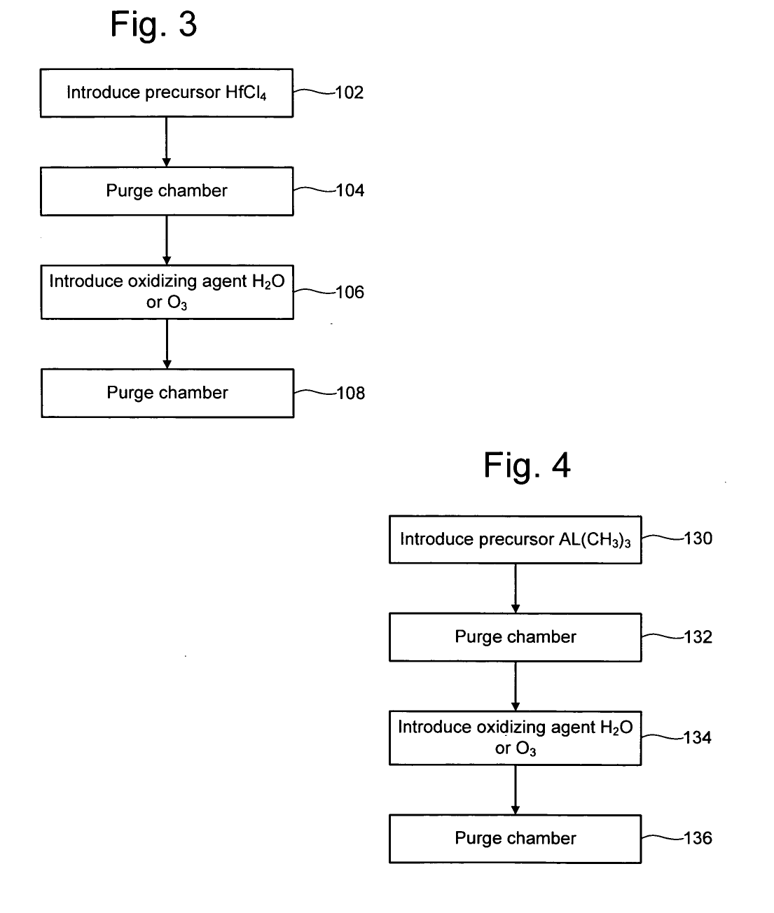

FIG. 4 is a flow chart describing one embodiment of a process for depositing one layer of Al₂O₃ using ALD. In step 130, the first precursor is introduced into the ALD chamber. In one example, the precursor is Al(CH₃)₃. In other embodiments, other precursors can be used. In some embodiments, the precursor is introduced using a gas, such as Argon or another inert gas. In step 132, the chamber is purged using an inert gas. In step 134, an oxidizing agent or other precursor can be introduced. Examples of a suitable oxidizing agent include H₂O, O₃, other oxidizing agents, or other precursors. In step 136, the ALD chamber is purged. At the end of the process of FIG. 4, one layer of Al₂O₃ has been deposited. Although FIGS. 3 and 4 describe the process using ALD to add a layer of HfO₂ and Al₂O₃, ALD can be used to add layers of other dielectric materials, which can be used for the present invention.

FIGS. 3 and 4 disclose a process for depositing a layer of a material. To some engineers, a layer may provoke the idea of a monolayer of material or a single molecular layer. In crystals such a layer is clearly defined. In amorphous materials such as the dielectrics described herein, a monolayer is not clearly defined. It should be noted that the term layer used herein refers to a thickness deposited in one ALD cycle. The thickness deposited may vary based on the materials, condition or cycle. For example, in steady state (not in the early incubation period), aluminum oxide is deposited at a rate of 0.8 A per cycle. This may constitutes less than one monolayer of aluminum oxide. The reason for sub-monolayer deposition per ALD cycle is that the first precursor does not completely cover the surface in any ALD cycle, the first precursor molecules only attach to active sites on the surface, and these active sites are not sufficient to allow a complete mono layer of deposited oxide per ALD cycle.

The two dielectric materials being deposited by ALD are added such that the mole fractions of each of the two materials varies as a function of depth in the dielectric layer in order to create the crested (e.g. rounded) bottom of the conduction band profile for that dielectric layer. For example, assume that within each region of the dielectric layer, the multiple dielectrics are added as (HfO₂)_{X}(Al₂O₃)_{1-X}, where the mole fraction of HfO₂ is X and the mole fraction of Al₂O₃ is 1-X. Alternatively, the multiple dielectrics can be added as (HfO₂)_{1-X l (Al}₂O₃)_{X}, where the mole fraction of HfO₂ is 1-X and the mole fraction of Al₂O₃ is X. In either case X can be a number greater than or equal to zero. The variable X will gradually change with depth in the dielectric layer. The switching of chemistry of the ALD deposited dielectrics every single cycle or every few cycles can create the gradual change in mole fraction to create the rounded barrier. An annealing process of proper duration and temperature may further smooth the changing of the of the mole fraction.

In one embodiment, the dielectric is divided into regions. Within each region, the dielectric components added using ALD (two or more components) will have particular mole fractions such that the mole fractions vary from region to region. That is, in one region, the components will have a first set of mole fractions while in another region, the components will have a second set of mole fractions. In other embodiments, however, the mole fraction can vary within the region. Other embodiments will not employ the use of regions.

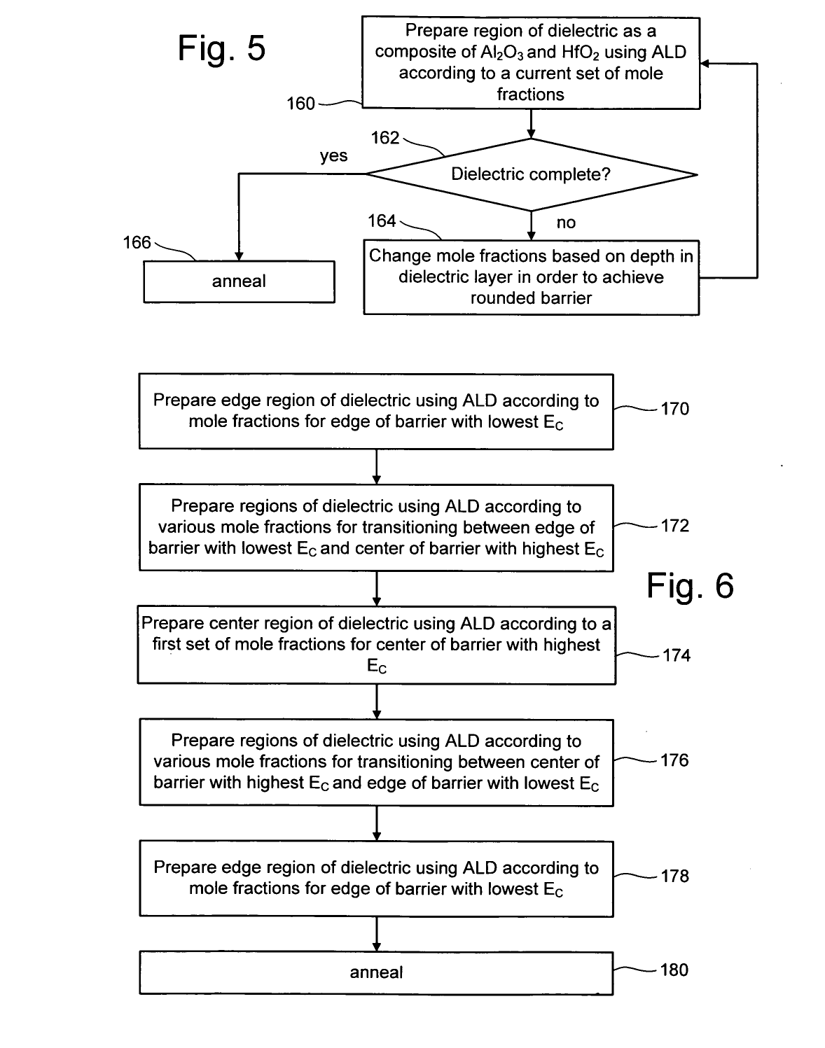

FIG. 5 is a flow chart describing one embodiment of creating a dielectric layer with multiple regions having different mole fractions. In step 160, a region of a dielectric is prepared as a composite of Al₂O₃ and HfO₂ using ALD according to a current set of mole fractions. In other embodiments, other components can be used. Step 160 is implemented by performing the processes of FIGS. 3 and 4 a certain number of times each, according to the desired mole fractions. In some embodiments, a region can be comprised of only one of the two components (e.g., 100% Al₂O₃ or 100% HfO₂) by having a mole fraction of zero for the excluded component. In step 162, it is determined whether the dielectric layer is complete. If not, the desired mole fractions are changed based on the depth of the dielectric layer in order to achieve a rounding barrier, in step 164. The process then loops back to step 160 to add the next layer using the new mole fractions. If in step 162, it is determined that the dielectric layer is complete, an annealing process is performed in step 166. FIG. 5 shows the annealing process being performed after all the layers of the dielectric region have been added using ALD. In another embodiment, the annealing process can be performed after each iteration of step 160, or at other time intervals.

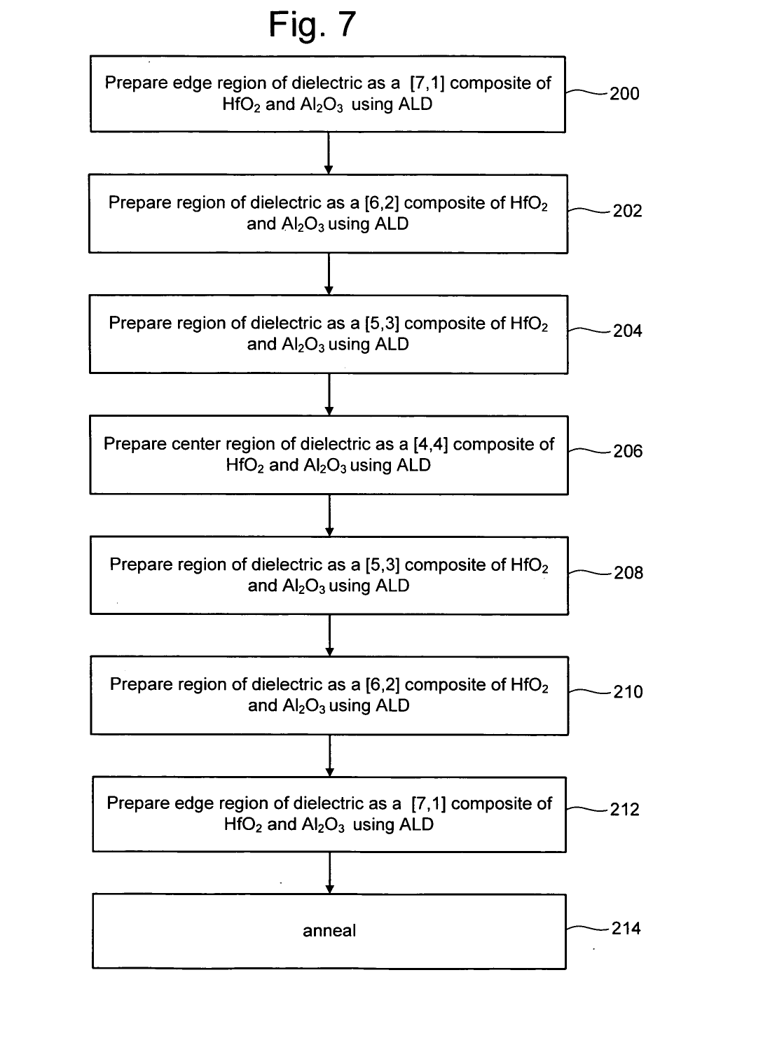

FIG. 6 is another flowchart describing an embodiment of creating a dielectric layer. FIG. 6 is one example of an implementation of the process of FIG. 5. In step 170 of FIG. 6, an edge region of the dielectric is created using ALD according to mole fractions for the edge of the barrier. The edge regions will have the lowest E_{C} of the various regions in the dielectric. This edge region is the region of the dielectric closest to the silicon substrate (e.g., see E1 of FIG. 2A). As can be seen from FIG. 2A, this area closest to the silicon substrate has the lowest E_{c}. Note that the portion of the dielectric in the middle of the dielectric region (C1 of FIG. 2A) has the highest E_{c}. The region closest to the polysilicon floating gate, which is also referred to as an edge region (see E2 of FIG. 2A), also has the lowest E_{c}. In one embodiment, the edge region is created as a composite of Al₂O₃ and HfO₂ using ALD according to mole fractions for the edge of the barrier. In another embodiment, the edge region is created as pure HfO₂.

In step 172, the process includes preparing the regions of the dielectric that are between the edge region and the center region of the dielectric layer. These regions created in step 172 are the transition regions. Each of these regions will be created using ALD as a composite of Al₂O₃ and HfO₂. Each region will have different mole fractions for the two components so that the mole fractions change as the regions get closer to the center of the dielectric in order for the bottom of the connection band to increase such that the profile is rounded.

In step 174, the center region of the dielectric layer is prepared using ALD according to a set of mole fractions for the center of the barrier. The center region has the highest E_{c}. In one embodiment, the center region is created as a composite of Al₂O₃ and HfO₂ using ALD according to mole fractions for the edge of the barrier. In another embodiment, the center regions is created as pure Al₂O₃.

In step 176, the regions of the dielectric that are transitioning between the center region and the edge region closest to the polysilicon floating gate are added. Each of these transition regions are created as a composite of Al₂O₃ and HfO₂ using ALD according to various mole fractions for transitioning between the center of the barrier with the highest E_{C} and the edge of the barrier with the lowest E_{c}.

In step 178, the edge region of the dielectric closest to the polysilicon floating gate is created using ALD according to mole fractions for the edge of the barrier with the lowest E_{C}. In one embodiment, the edge region is created as a composite of Al₂O₃ and HfO₂ using ALD according to mole fractions for the edge of the barrier. In another embodiment, the edge region is created as pure HfO₂.

In step 180, an annealing process is performed. As noted above, the annealing process can be performed at other times in addition to or instead of when depicted in FIG. 6. In some cases, the annealing may result in the components (e.g., Al₂O₃ and HfO₂) mixing together. The degree of mixing (e.g. partial mixing together) may vary based on the annealing process. The mixing is a result of inter-diffusion of various materials into one another. This will take place at elevated temperatures typically above 700 C and is highly dependent on temperature value, exposure time to the elevated temperatures, and the materials involved.

In one embodiment, each region of the dielectric will be composed of eight layers of dielectric material. That is, eight iterations of one or more ALD processes will be used to create eight layers, which will comprise one region of the dielectric layer. In one example implementation, there may be seven such regions; therefore, the dielectric layer will include 56 layers. In other embodiments, more or less than eight layers can be used within each region, and more or less than seven regions can be used.

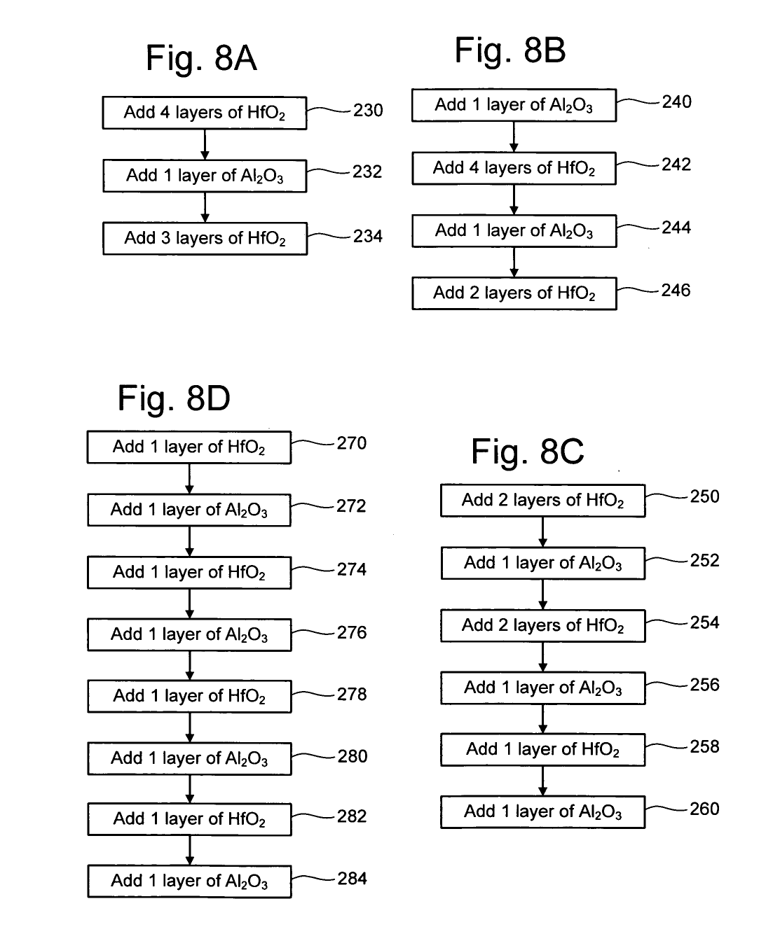

FIG. 7 is a flowchart describing an embodiment of a process for preparing a dielectric composed of seven regions, where each region includes eight layers of dielectric material. The mole fraction of the two components will vary from region to region, as a function of depth in the oxide, in order to create a rounded bottom of a conduction band profile for the dielectric layer. (See FIG. 2A.) Each of the eight layers of dielectric material within a region will be added by performing the processes of FIG. 3 or 4. In other embodiments, materials other than the HfO₂ and Al₂O₃ will be used. In step 200, the edge region is prepared as a [7,1] composite of HfO₂ and Al₂O₃ (or other materials) using ALD. A [7,1] composite includes seven layers of HfO₂ and one layer of Al₂O₃. In step 202, the next region of the dielectric is created as a [6,2] composite of HfO₂ and Al₂O₃ (or other materials) using ALD. The [6,2] composite includes six layers of HfO₂ and two layers of Al₂O₃. In step 204, the next region is prepared as a [5,3] composite of HfO₂ and Al₂O₃ (or other materials). The [5,3] composite includes five layers of HfO₂ and three layers of Al₂O₃. In step 206, a center region of the dielectric is prepared. The center region is a [4,4] composite of HfO₂ and Al₂O₃ (or other materials). The [4,4] composite includes four layers of HfO₂ and four layers of Al₂O₃. In step 208, the next region of the dielectric is prepared as a [5,3] composite of HfO₂ and Al₂O₃ (or other materials). In step 210, the next region of the dielectric is prepared as a [6,2] composite of HfO₂ and Al₂O₃ (or other materials). In step 212, the edge region (closest to the polysilicon floating gate) is prepared as a [7,1] composite of HfO₂ and Al₂O₃ (or other materials) using ALD. In step 214, an annealing processes is performed. As described above, the annealing process can be performed at other times instead of or in addition to the time after step 212.

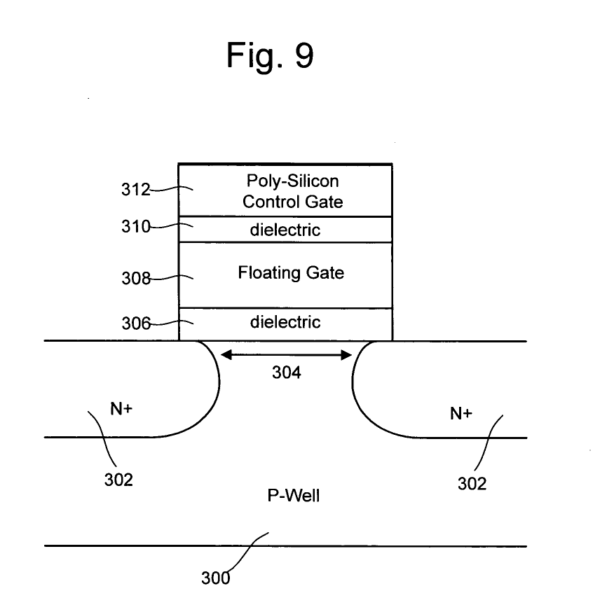

Steps 200 and 212 include preparing a dielectric as a [7,1] composite of HfO₂ and Al₂O₃. There are various different configurations for adding seven layers of HfO₂ and one layer of Al₂O₃. The flowchart of FIG. 8A provides one example of creating a [7,1] composite. However, other configurations can also be used. In step 230 of FIG. 8a, four layers of HfO₂ are added. In one embodiment, step 230 is implemented by performing the process of FIG. 3 four times. In step 232 of FIG. 8a, one layer of Al₂O₃ is added. In one embodiment, step 232 is performed by performing the process of FIG. 4 one time. In step 234, three layers of HfO₂ are added. In one embodiment, step 234 is implemented by performing a process of FIG. 3 three times.

Steps 202 and 210 of FIG. 7 include creating a [6,2] composite. There are various configurations to create such a composite. One example is created using the process of FIG. 8B. However, other configurations can also be used. In step 240, one layer of Al₂O₃ is added. In step 242, four layers of HfO₂ are added. In step 244, one layer of Al₂O₃ is added. In step 246, two layers of HfO₂ are added. Note that each layer of Al₂O₃ is added using the process of FIG. 4, and each layer of HfO₂ is added using the process of FIG. 3.

Step 204 and Step 208 include creating a [5,3] composite. FIG. 8C provides one example of creating such a [5,3] composite. Other configurations can also be used. In step 250 of FIG. 8C, two layers of HfO₂ are added. In step 252, one layer of Al₂O₃ is added. In step 254, two layers of HfO₂ are added. In step 256, one layer of Al₂O₃ is added. In step 258, one layer of HfO₂ is added. In step 260, one layer of Al₂O₃ is added. Note that each layer of Al₂O₃ is added using the process of FIG. 4, and each layer of HfO₂ is added using the process of FIG. 3.

Step 206 of FIG. 7 includes adding a region of the dielectric, which is a

composite. FIG. 8D describes a flowchart describing one example of creating such a composite. Other configurations can also be used. In step 270, one layer of HfO₂ is added. In step 272, one layer of Al₂O₃ is added. In step 274, one layer of HfO₂ is added. In step 276, one layer of Al₂O₃ is added. In step 278, one layer of HfO₂ is added. In step 280, one layer Al₂O₃ is added. In step 282, one layer of HfO₂ is added. In step 284, one layer of Al₂O₃ is added. Each layer of HfO₂ is added according to the process of FIG. 3. Each layer of Al₂O₃ is added according to the process of FIG. 4.

In one embodiment of a process for using ALD to add multiple layers of a two or more components having varying mole fractions as a function of depth to form a dielectric layer, the mole fractions at the edges and/or center of one of the components can be zero. The resulting dielectric would then be composed of a first material at the two edges and a second material at the center, with a composition that gradually changes from the first material to the second material moving from either dielectric edge towards the center of the dielectric. For example, looking at FIG. 2A, a material layer composed of hafnium oxide can be used at the two edges and silicon dioxide at the center, with a composition that gradually changes from hafnium oxide to silicon dioxide when moving from either dielectric edge towards the center of the dielectric. The portion of the dielectric that gradually changes from first material to the second material can include all or a subset of the regions created by steps 200-214 of FIG. 7. It should be noted that the material at the center is not required to be pure silicon dioxide, and neither do the materials at the two dielectric interfaces need be pure hafnium oxide. The entire dielectric may be composed of hafnium silicon oxide with higher concentrations of hafnium at the edges and higher concentration of silicon at the center. Even if pure silicon oxide is deposited at the center and pure hafnium oxide is deposited at the interfaces, some subsequent thermal processes would reduce the purities of these regions through inter-diffusion at elevated temperatures.

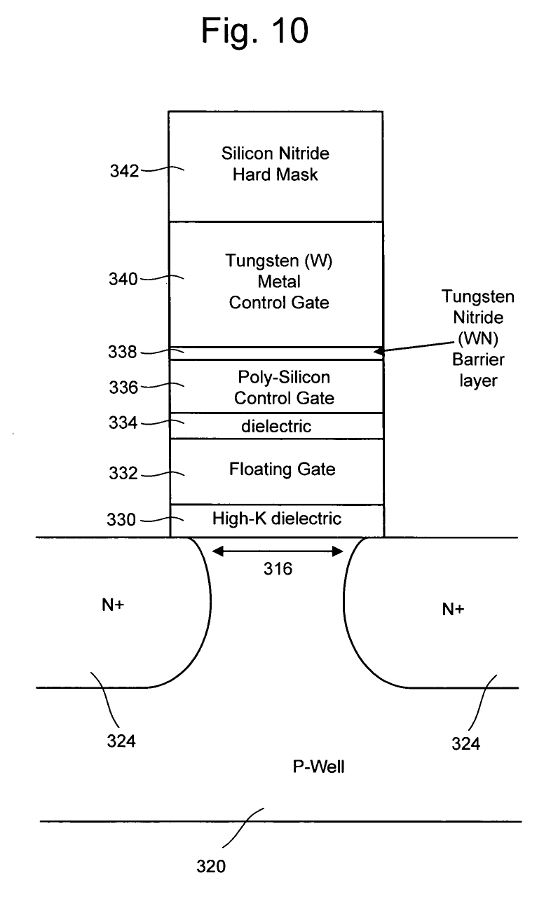

The dielectric layer described above can be used in various devices, components, etc. In one example, the dielectric layer is used as a tunnel dielectric for a flash memory cell. FIG. 9 depicts one example of a flash memory cell that can use the dielectric layer described above. The flash memory cell of FIG. 9 includes a triple well comprising a P-substrate, an N-well and a P-well 300. The P-substrate and the N-well are not depicted in FIG. 9 in order to simplify the drawing. Within P-well 300 are N+ diffusion regions 302, which serve as source/drain regions. Between N+ diffusion regions 302 is a channel 304. Above channel 304 is dielectric layer 306. Above dielectric layer 306 is a floating gate 308. Above floating gate 308 is a second dielectric layer 310. Above dielectric layer 310 is a polysilicon control gate 312.

To program the memory cell, electrons tunnel through dielectric layer 306 into floating gate 308. To erase the memory cell of FIG. 9, electrons tunnel from floating gate 308 across tunnel dielectric 306. Tunnel dielectric 306 is made according to the processes described above. That is, tunnel dielectric 306 is made of two or more components (e.g., HfO₂ and Al₂O₃), where both those components are added using ALD with varying mole fractions as a function of depth in the dielectric layer in order to create a rounded (or otherwise crested) bottom for a conduction band profile for the dielectric layer 306 (See FIG. 2A.).

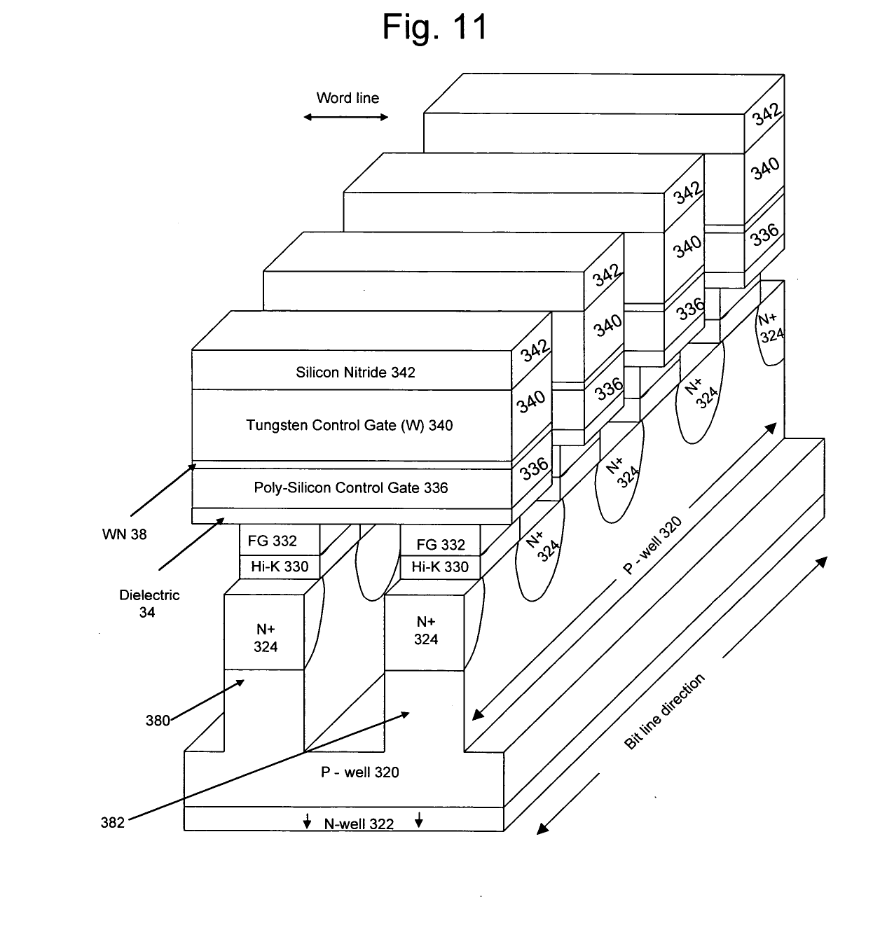

FIG. 10 is a two-dimensional block diagram of another embodiment of a flash memory cell that can utilize a dielectric layer according to the present invention. The memory cell of FIG. 10 includes a triple well comprising a P substrate, a N-well and a P-well 320. The P substrate and the N-well are not depicted in FIG. 10 in order to simplify the drawing; however, they are depicted in another drawing described below. Within P-well 320 are N+ diffusion regions 324, which serve as source/drains. Whether N+ diffusion regions 324 are labeled as source regions or drain regions is somewhat arbitrary; therefore, the N+ diffusion source/drain regions 324 can be thought of as source regions, drain regions, or both.

Between N+ diffusion regions 324 is the channel 316. Above channel 316 is dielectric layer 330. Above dielectric area 330 is floating gate 332. Above floating gate 332 is dielectric layer 334. Dielectric layer 334 is made according to the processes described above. That is, dielectric layer 334 is made of two or more components (e.g., HfO₂ and Al₂O₃), where both those components are added using ALD with varying mole fractions as a function of depth in the dielectric layer in order to create a rounded (or otherwise crested) bottom for a conduction band profile for the dielectric layer 334. (See FIG. 2A.).

Above dielectric area 334 is a poly-silicon layer of control gate 336. Above poly-silicon layer 336 is a conductive barrier layer 338 made of Tungsten Nitride (WN). Above barrier layer 338 is a low resistivity metal gate layer 340 made of Tungtsen. WN layer 338 is used to reduce the inter-diffusion of Tungsten into the poly-silicon layer of control gate 336, and also of silicon into Tungsten layer 340. Note that, in one embodiment, control gate 336 consists of layers 336, 338, and 340 as they combine to form one electrode. In other embodiments, a single metal layer, or multiple metal layers without using a poly control gate sub-layer 336 can be used. Dielectric 330, floating gate 332, dielectric 334, poly-silicon layer of control gate 336, WN layer 338 of control gate, and Tungsten metal layer 340 of control gate comprise a stack. An array of memory cells will have many such stacks.

Various sizes and materials can be used when implementing the memory cell of FIG. 1. In one embodiment, dielectric 330 is 14 nm and includes a high-K material. In other embodiments, dielectric 330 can be 8 nm-15 nm. Examples of high-K materials that can be used in dielectric 330 include Aluminum Oxide Al₂O₃, Hafnium Oxide HfO₂, Hafnium Silicate HfSiO_{X}, Zirconium Oxide, or laminates and/or alloys of these materials. Other high-K materials can also be used.

Use of high-K dielectric materials between the crystalline silicon channel, and a poly gate typically creates two interfacial layers above and below the high-K material itself. These interfacial layers are composed of SiO₂, or Silicon Oxy-nitride (SiON), with some fraction of metal atoms that may have diffused from the high-K material itself. These interfacial layers are usually formed naturally and not intentionally, and in many applications these interfacial layers are undesirable, as their dielectric constant tends to be substantially lower than the dielectric constant of the high-K material. In this embodiment, because the high-K dielectric is substantially thicker than that used for gate dielectrics of advanced MOS logic transistors, an interfacial layer that is 1 nm thick or even thicker may not only be tolerable, but also a welcome feature. This will especially be the case if the lower K interfacial layer provides higher mobility for channel electrons, and/or higher immunity to leakage currents because of the higher energy barrier (bottom of the conduction band offset) that the interfacial layer may offer. Higher energy barriers reduce the possibility of electron injection into the high-K dielectric by both direct tunneling, and Fowler-Nordheim (FN) tunneling. Silicon nitride or other inter-diffusion barrier insulators and oxygen diffusion barrier insulators may also be deposited or grown at the interface of silicon and high-K material in order to impede inter-diffusion of various atoms across material boundaries and/or impede further growth of interfacial silicon oxide layers. Toward these ends, in some embodiments, layers of silicon oxide and/or silicon nitride may be intentionally grown and/or deposited to form part of the interfacial layers above and/or below the high-K dielectric(s).

Floating gate 332 is 20 nm and is typically made from poly-silicon that is degenerately doped with n-type dopants; however, other conducting materials, such as metals, can also be used. Dielectric 334 is 10 nm and is made of SiO₂; however, other dielectric materials can also be used. Control gate sub layer 336 is 20 nm and is made from poly-silicon; however, other materials can also be used. The WN conducting diffusion barrier layer 338 is 4 nm thick. Tungsten metal control gate layer 340 is 40 nm thick. Other sizes for the above described components can also be implemented. Additionally, other suitable materials, such as replacing W/WN with Cobalt Silicide, can also be used. The floating gate and the control gate can also be composed of one or more layers of poly-silicon, Tungsten, Titanium, or other metals or semiconductors.

As mentioned above, dielectric 330 includes a high-K material. A “high-K material” is a dielectric material with a dielectric constant K greater than the dielectric constant of silicon dioxide. The dielectric constant K of silicon dioxide is in the range 3.9 to 4.2. For the same actual thickness, a high-K material will provide more capacitance per unit area than silicon dioxide (used for typical dielectric regions). In the background discussion above, it was stated that as channel size becomes smaller, the thickness of the dielectric region between the channel and the floating gate should be reduced. What is learned is that it is the effective thickness that must be reduced because it is the effective thickness that determines the control of the floating gate over the channel. Effective thickness is determined as follows:

$$EffectiveThickness = \frac{ActualThickness}{actualK / SiliconDioxideK}$$

where Actual Thickness is the physical thickness of the dielectric region, actualK is the dielectric constant for the material used in the dielectric region and SiliconDioxideK is the dielectric constant for SiO₂.

A high-K material will have an effective thickness that is lower than its actual thickness. Therefore, a high-K material can be used with a smaller channel size. The smaller effective thickness accommodates the smaller channel size, allowing the gate to maintain the appropriate influence over the channel. The larger actual thickness of a high-K material helps prevent the leakage discussed above.

In one embodiment, the programming and erasing is performed by transferring charge (e.g., tunneling) between floating gate 332 and control gate 336, across dielectric 334. This is advantageous because the programming mechanism (e.g. tunneling) is now not so burdened with strong coupling. Rather, the strong steering function is placed between the floating gate and the channel, matching the strong channel coupling dictate for scaled channels. Thus, the memory cell of FIG. 10 has interchanged dielectric roles. Namely, a high-K dielectric and associated steering function placed between floating gate 332 and channel 316, and non-scaled down tunnel oxide (e.g. ˜>85 Å, targeted towards high reliability, minimal leakage current) between control gate 336 and floating gate 332. Thus, in some embodiments, dielectric 334 serves as the tunnel oxide.

Some advantages which may be realized with some embodiments of the above described memory cell includes the ability to properly scale the device; wear associated with program/erase can be confined to the inter-gate region (away from the channel), which can increase endurance; lower program/erase voltages and/or higher reliability by using thicker dielectrics; and the elimination of the need to aggressively scale tunnel oxide of traditional NAND (or flash memories with other architectures such as NOR). A designer of a memory cell according to the present invention should be mindful of GIDL and a lower control gate coupling ratio (less Q_{fg}, stronger magnification of channel noise and larger manifestations of cell-to-cell variations).

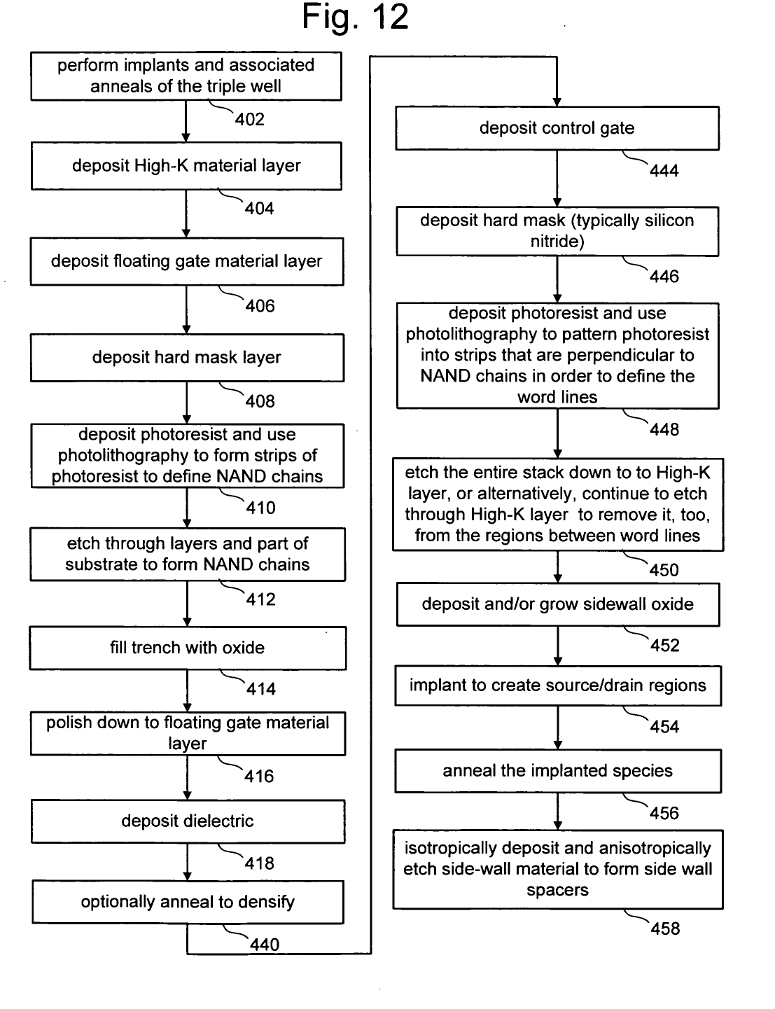

In one embodiment, the memory cell of FIG. 10 is a NAND type flash memory cell. In other embodiments, other types of flash memory cells can be used. FIG. 11 is a three dimensional drawing of two NAND strings 380 and 382 according to one embodiment of the present invention. FIG. 11 depicts four memory cells on strings 380 and 382; however, more or less than four memory cells can be used. For example, typical NAND strings consist of 16, 32 or 64 NAND cells in series. Other sizes of NAND strings can also be used with the present invention. Each of the memory cells has a stack as described above with respect to FIG. 10. FIG. 11, further depicts. N-well 322 below P-well 320, the bit line direction along the NAND string and the word line direction perpendicular to the NAND string. The P-type substrate below the N-well is not shown in the FIG. 11. In one embodiment, the control gates form the word lines. In another embodiment, the control gate poly-silicon layer 336, WN layer 338 and Tungsten layer 340 form the word lines or control gates. In many embodiments, a Silicon Nitride layer 342 is above the Tungsten layer 40, and serves as a hard mask for etching the multiple gate stacks to form individual word lines. Another purpose of the nitride (or other material) hard mask is to provide a thickening of spacers that can be formed on the side walls of the stacks by moving the thinning regions of the spacers further away from the control conducting word lines and placing the thinning portions of the spacers vis-à-vis the nitride hard mask residing on top of the upper-most control gate sub-layer.

The memory cells described in FIGS. 1-4A are to be distinguished in their program and erase characteristics from that of prior NAND devices. In prior devices the control gate attempts to tightly couple to the floating gate and control its potential with respect to the substrate, causing electrons to tunnel from floating gate to substrate when the floating gate is sufficiently negative with respect to the substrate (erase; control gate held at ground, substrate raised to high voltage), or to tunnel from the substrate to the floating gate when the floating gate is sufficiently positive with respect to the substrate (program; substrate held at ground, control gate raised to a variable high voltage). Since the substrate is in common with many memory cells, it is convenient to apply a high fixed voltage to it, but it is not convenient to apply a variable low or negative voltage to a common word line connecting multiple control gates, and thereby selectively control the degree of electron removal from these different cells. Thus the “erase” condition is used to refer to removal of substantially “all” electrons from a collection of cells, setting all of them to a common low threshold state, typically a negative value. The erase of multiple cells is then followed by a variable program cycle that can be terminated on a cell by cell basis to set each cell to a unique state while continuing to program other cells on the same word line to a different state, as described earlier.

In the present devices the substrate is tightly coupled to the floating gate via the high dielectric constant material and the control gate is relatively weakly coupled to the floating gate so that reversing the polarity of the definition of erase and program is convenient. That is, when the substrate is raised to a high potential, the floating gate is also raised to a relatively high potential, and many electrons are transferred to the floating gate by tunneling from a grounded control gate, resulting in the collection of cells having a high threshold as viewed from the control gate. Programming, or setting a variable threshold to represent the data state, is accomplished by selectively removing some electrons by raising the control gate in a controlled fashion and terminating the electron removal on a cell by cell basis. This results in selectively reducing the threshold voltage as seen from the control gate, in direct contrast to the prior art devices. This will be described more completely below in conjunction with FIGS. 6-8.

In one example, the drain and the p-well will receive 0 volts while the control gate receives a set of programming pulses with increasing magnitudes. In one embodiment, the magnitudes of the pulses range from 7 volts to 15 volts. In other embodiments, the range of pulses can be different. During programming of a memory cell, verify operations are carried out in the periods between the pulses. That is, the programming level of each cell of a group of cells being programmed in parallel is read between each programming pulse to determine whether it is equal to or greater than a verify level to which it is being programmed.

The memory cells of FIGS. 10-11 are erased by transferring charge from the control gate to the floating gate. For example, electrons are transferred from the control gate to the floating gate via Fowler-Nordheim tunneling. In other embodiments, other mechanisms can be used. In one embodiment, erase is performed by applying 15 volts (or another suitable level) to the p-well, floating the source/drains and applying 0 volts to the control gate.

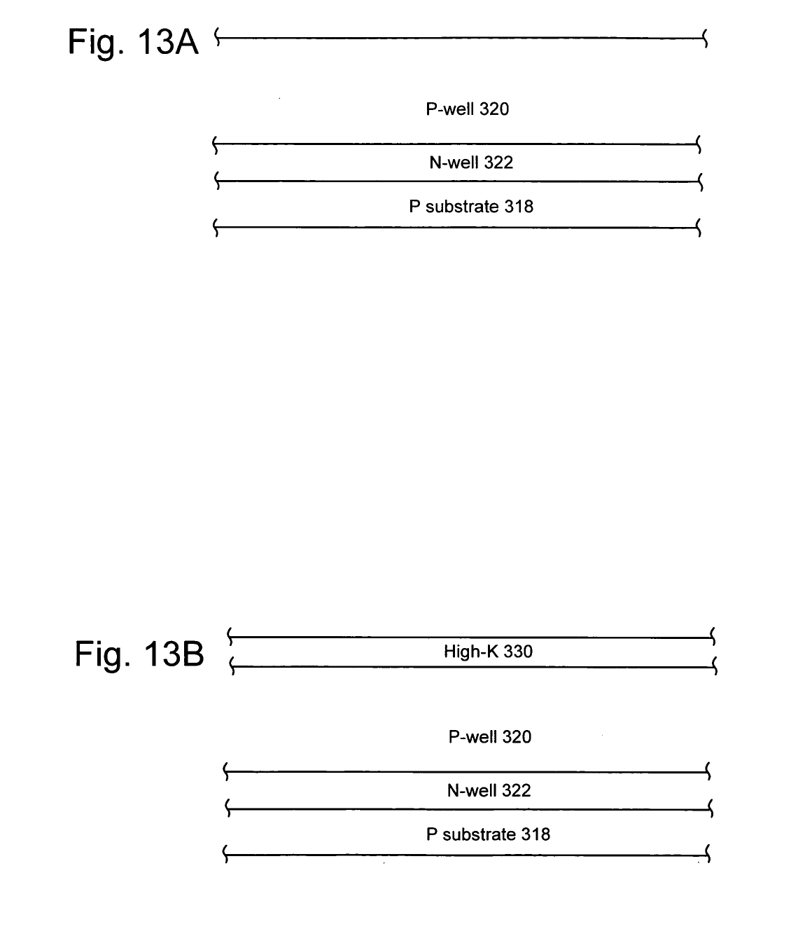

FIG. 12 is a flow chart describing one embodiment of the front end of a process for manufacturing the memory cell of FIG. 10, which covers process steps only as far as forming sidewall spacers. There are many ways to manufacture memory according to the present invention and, thus, the inventors contemplate that various methods other than that described by FIG. 12 can be used. While a flash memory chip will consist of both a peripheral circuitry, which includes a variety of low, medium, and high voltage transistors, and the core memory array, the process steps of FIG. 9 are intended only to describe in general terms one possible process recipe for the fabrication of the core memory array. Many photolithography, etch, implant, diffusion and oxidation steps that are intended for the fabrication of the peripheral transistors are omitted.

It should be noted that in flash memory chips, the convention has been to use the same floating gate oxide that is used between the floating gate and the channel for the gate oxide of low, and some medium voltage transistors in order to save extra process steps. Therefore the conventional tunnel oxide with a thickness that is usually greater than 8 nm has been limiting the performance, sub-threshold slope, and on-current drive of the low and some medium voltage transistors. This has resulted in slower program, and read characteristics. One advantage of the present invention is to provide a peripheral transistor gate oxide that is electrically and effectively much thinner than the conventional tunnel oxide, and is physically thicker than the conventional tunnel oxide. In other words, the peripheral circuitry will benefit from replacing the conventional tunnel oxide gate with high-K material(s) in alignment with the general trend of the semiconductor industry towards high-K materials.

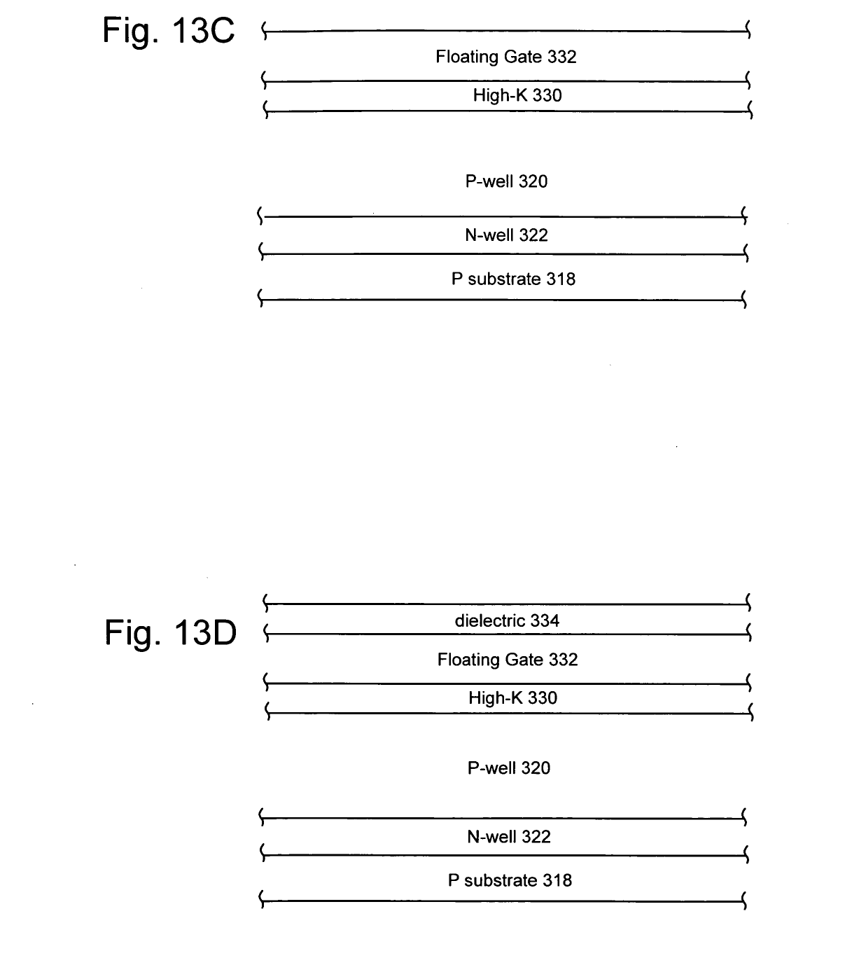

Step 402 of FIG. 12 includes performing implants and associated anneals of the triple well. The result of step 402 is depicted in FIG. 13A, which depicts P substrate 318, N-well 322 within P-substrate 318, and P-Well 320 within N-well 322. The sidewalls of the N-well that isolate the P-wells from one another are not depicted. Also the N-well depth is typically much thicker than that of the P-well in contrast to FIG. 13A. The P substrate is usually the thickest consisting of the majority of the wafer thickness. In step 404, the high-K material(s) is deposited on top of P-Well 320. The high-K material is deposited using Chemical Vapor Deposition (CVD) including Metal Organic CVD (MOCVD), Physical Vapor Deposition (PVD), Atomic Layer Deposition (ALD), or another suitable method. Additionally (and optionally), other materials may be deposited on, deposited under or incorporated within the high-K material in order to form dielectric layer 330. The result of step 404 is depicted in FIG. 13B, which shows dielectric layer 330, with the high-K material. Note that one advantage of using the high-K material in the lower dielectric layer is that it can also be used for low voltage peripheral transistors to increase performance.

In step 406, the floating gate is deposited over dielectric layer 330 using CVD, PVD, ALD or another suitable method. The result of step 406 is depicted in FIG. 13C, which shows floating gate layer 332 deposited on top of high-K dielectric layer 330.

Step 408 of FIG. 12 includes depositing a hard mask using, for example, CVD, to deposit SiO₂ or Si₃N₄. In step 410, photolithography is used to form strips of photoresist over what will become the NAND chains. Step 412 includes etching through all layers, including part of the substrate. First, the hard mask is etched through using anisotropic plasma etching, (i.e. reactive ion etching with the proper balance between physical and chemical etching for each planar layer encountered). After the hard mask layer is etched into strips, the photoresist can be stripped away and the hard mask layer can be used as the mask for etching the underlying layers. The process, then includes etching through the floating gate material, the high-K dielectric material and approximately 0.1 micron into the substrate to create trenches between the NAND strings, where the bottom of the trenches are inside the top P-well 320. In step 414, the trenches are filled with SiO₂ (or another suitable material) up to the top of the hard mask using CVD, rapid ALD or PSZ STI fill as described in “Void Free and Low Stress Shallow Trench Isolation Technology using P-SOG for sub 0.1 Device” by Jin-Hwa Heo, et. al. in 2002 Symposium on VLSI Technology Digest of Technical Papers, Session 14-1. PSZ STI fill is Polysilazane Shallow trench isolation fill. The fill sequence includes spin coat by coater, and densify by furnace. Si—N bond conversion to Si—O bond enables less shrinkage than conventional SOG (Spin On Glass). Steam oxidation is effective for efficient conversion. One proposal is to use Spin-On-Glass (SOG) for the dielectric layer, which is called polysilazane-based SOG (SZ-SOG), a material used in integrating the inter layer dielectric (ILD) applications because of its excellent gap filling and planarization properties, and thermal oxide like film qualities. In step 416 Chemical Mechanical Polishing (CMP), or another suitable process, is used to polish the material flat until reaching the floating gate poly-silicon. The floating gate is polished to 20 nm (10-100 nm in other embodiments).

In step 418, the inter-poly tunnel dielectric 334 is deposited using ALD. Dielectric layer 334 is made according to the processes described above. That is, dielectric layer 334 is made of two or more components (e.g., HfO₂ and Al₂O₃), where both those components are added using ALD with varying mole fractions as a function of depth in the dielectric layer in order to create a rounded (or otherwise crested) bottom for a conduction band profile for the dielectric layer 334 (See FIG. 2A.). FIG. 13D, which shows the inter-poly dielectric region 334 over floating gate 332, depicts the device after step 418.

In step 440 of FIG. 12, which is an optional step (or can be part of step 418), the inter-poly tunnel oxide is annealed to densify the oxide, without damaging the high-K materials due to a high temperature. Note that Al₂O₃ will crystallize at approximately 800 degrees Celsius, HfO₂ will crystallize at approximately 500 degrees Celsius, HfSiOₓ will crystallize at approximately 1100 degrees Celsius, and HfSiON will crystallize at approximately 1300 degrees Celsius. In general, longer exposure times to high temperatures will result in reduced crystallization temperatures. Some of the most reliable tunnel oxides are grown Silicon Oxi-Nitride, grown Silicon Oxide, and low temperature grown oxide by Oxygen Radical generation in high density Krypton plasma at temperatures as low as 400 degrees Celsius. In step 444, the one or more layers of the control gate are deposited on the inter-poly tunnel oxide. In one embodiment, the materials deposited during step 444 include poly-silicon (e.g. layer 336), while in other embodiments this layer may be a metal layer with a proper work function, thermal stability, and etch characteristics. In some embodiments, the control gate is composed of the poly-silicon layer 336, tungsten-nitride layer 338, and tungsten layer 340, all of which are deposited in step 444. Nitride layer 338 and tungsten layer 340 are deposited to reduce the control gate sheet resistance and form lower resistivity word lines. These materials can be deposited in a blanket form using CVD, ALD, PVD or other suitable process. FIG. 13E, which shows poly-silicon control gate 336, WN layer 338 and Tungsten metal layer 340 over inter-poly tunnel oxide 334, depicts the device after step 444.

On top of the Tungsten layer, a hard mask of Si₃N₄ is deposited using, for example, CVD in step 446. In step 448, photolithography is used to create patterns of perpendicular strips to the NAND chain, in order to etch the multi-gate stack and form word lines (i.e. control gates) that are isolated from one another. In step 450, etching is performed using plasma etching, ion milling, ion etching that is purely physical etching, or another suitable process to etch the various layers and form the individual word lines. In one embodiment, the etching is performed until the high-k material is reached. The process attempts to leave as much high-K material as possible, but tries to etch completely through the floating gate material. In another embodiment, the process will etch all the way to the substrate. FIG. 13F, which shows the stack, depicts the device after step 450. Note that the size of the p-well, n-well and P substrate are not necessarily drawn to scale.

In step 452, sidewall oxidation, sidewall oxide deposition, or a combination of the two is performed. For side wall oxidation, the device is placed in a furnace at a high temperature and some fractional percentage of ambient oxygen gas, so that the exposed surfaces oxidize, which provides a protection layer. Sidewall oxidation can also be used to round the edges of the floating gate and the control gate. An alternative to high temperature (e.g. over 1000 degrees Celsius) oxide growth is low temperature (e.g. 400 degrees Celsius) oxide growth in high density Krypton plasma. More information about sidewall oxidation can be found in “New Paradigm of Silicon Technology,” Ohmi, Kotani, Hirayama and Morimoto, Proceedings of the IEEE, Vol. 89, No. 3, March 2001; “Low-Temperature Growth of High Silicon Oxide Films by Oxygen Radical Generated in High Density Krypton Plasma,” Hirayama, Sekine, Saito and Ohmi, Dept. of Electronic Engineering, Tohoku University, Japan, 1999 IEEE; and “Highly Reliable Ultrathin Silicon Oxide Film Formation at Low Temperature by Oxygen Radical Generated in High-Density Krypton Plasma,” Sekine, Saito, Hirayama and Ohmi, Tohoku University, Japan, 2001 IEEE; all three of which are incorporated herein by reference in their entirety. Another way to deposit low temperature tunnel oxide may be by using Krypton Plasma, in conjunction with atomic layer deposition of Silicon Oxide or silicon Oxi-Nitride.

To achieve uniform tunneling a processing step may be employed in order to make the inter-gate tunnel dielectric thicker at the edges where the field lines may be more concentrated than near the middle. Oxidation may be a suitable way of achieving this end.

In step 454, an implant process is performed to create the N+ source/drain regions by Arsenic implantation. In one embodiment, a halo implant is also used. In step 456, an anneal process is performed. In one embodiment, a low temperature anneal process is performed to prevent damage to the high-K material. In some embodiments, a high-K material can be used that has a high thermal budget (e.g., able to endure high temperatures without degrading). In step 458, the process includes isotropically depositing and aniotropically etching sidewall material to form sidewall spacers.

In another embodiment, the methods and technologies described above can be applied to fabricate gradually changing barriers that are of the crested-K type as opposed to crested energy type as described earlier. A crested-K type tunnel barrier consists of a barrier where the dielectric constant or K of the barrier is maximized near the center point of the barrier thickness and the K value is made to diminish at points closer to the tunnel dielectric interfaces. Typically, a reduction in K is concomitant with an increase in barrier height, in terms of both the bottom of the conduction band barrier for electron tunneling and the top of valence band barrier for hole tunneling. Such a crested-K barrier is described in the article titled “Engineering of Conduction Band—Crested Barriers or Dielectric Constant—Crested Barriers in view of their application to floating-gate non-volatile memory devices” by J. Buckley, et al., and published in IEEE 2004 Silicon Nanoelectronics workshop, incorporated herein by reference in its entirety. The article titled “VARIOT: A Novel Multilayer Tunnel Barrier Concept for Low-Voltage Nonvolatile Memory Devices” by B. Govoreanu, et. al., and published in IEEE ELECTRON DEVICE LETTERS, VOL. 24, NO. 2, FEBRUARY 2003 also addresses a Crested-K tunnel barrier and is incorporated herein by reference in its entirety.

The crested-K tunnel barrier has the advantage of placing the higher quality silicon oxide, which suffers from the least amount of trapping and surface states, adjacent the channel in conventional floating gate memory embodiments where the tunnel oxide resides between the channel and the floating gate. This higher quality interface layer improves mobility, and reduces RTS noise and VT fluctuations. The disadvantage of the K-crested tunnel barrier is that a potential well is formed by the tunnel dielectric as a result of the change in composition. This potential well can lead to enhanced trapping by trap sites within deeper portions of the dielectric. The potential well can persist under the application of high tunneling electric fields. The longer time constants associated with trapping and de-trapping of these deeper trap sites can lead to greater levels of noise and charge relaxation issues that are discussed in more detail in U.S. Pat. No. 6,850,441 Titled “Noise reduction technique for transistors and small devices utilizing an episodic agitation”, incorporated herein by reference in its entirety.

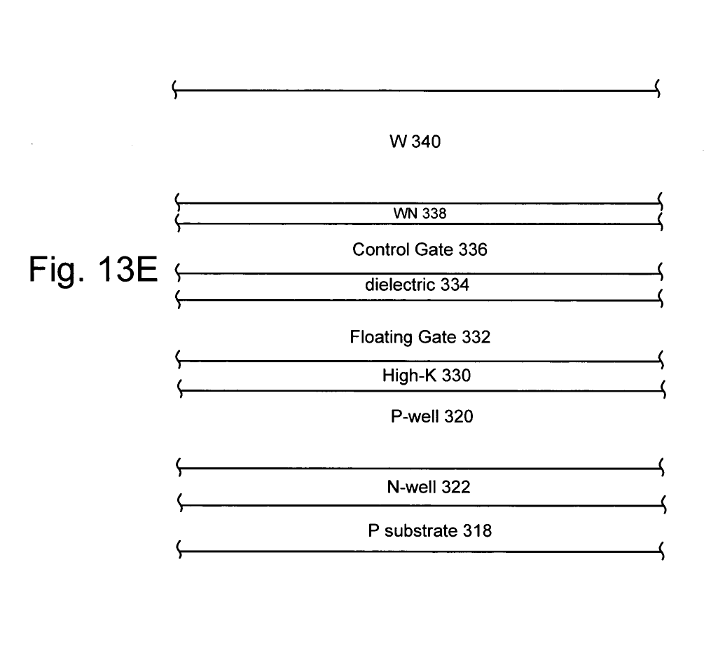

FIG. 14A illustrates the band structure of a Si/smoothly K-crested barrier/PolySi structure with an ALD deposited tunnel dielectric. As drawn, this figure roughly illustrates a material layer composed of silicon dioxide at the two edges and hafnium oxide at the center, with a composition that gradually changes from hafnium oxide to silicon dioxide when moving from the center to either of the dielectric edges.

When an electric field is applied to a device according to FIG. 14A, the conduction band and valance bands change as depicted in FIG. 14B. The application of a smaller voltage will result in electron tunneling through this dielectric. The transition form non-conducting to conducting dielectric occurs over a significantly smaller voltage range in this dielectric as compared to a uniform dielectric such as silicon dioxide. This is because of the higher degree of band bending in lower-K interface layers and availability of close-by energy states at small (1-2 nm) distance within the depth of the tunnel dielectric for electrons to tunnel into by elastic direct tunneling.

FIG. 14C shows the band structure of a Si/smoothly K-crested barrier/PolySi structure with an ALD deposited tunnel dielectric. As drawn, this figure roughly illustrates a material layer composed of silicon dioxide at the two edges and hafnium oxide at the center, with a composition that gradually changes from hafnium oxide to silicon dioxide moving from the center to either of the dielectric edges, and the interface layers near the edges are composed entirely of silicon dioxide for a thickness of 1 to 2 nm of this interface layers.

When an electric field is applied to a device according to FIG. 14C, the conduction band and valance bands change as depicted in FIG. 14D. The application of a smaller voltage will result in electron tunneling through this dielectric. The transition form non-conducting to conducting dielectric occurs over a significantly smaller voltage range in this dielectric as compared to a uniform dielectric such as silicon dioxide. This is because of higher degree of band bending in lower-K interface layers and availability of close-by energy states at small (1-2 nm) distance within the depth of the tunnel dielectric for electrons to tunnel into by elastic direct tunneling.

The energy band diagrams illustrate that electrons with energies within a few kT's of the Fermi level in the cathode can tunnel through a thin (1 nm to 3 nm), low-K, high band gap interface layer at the cathode, by direct tunneling into available energy states above the bottom of the conduction band of the high-K, low band gap layer. The electric field in the low-K interface layer is higher than the electric field in the high-K layer. The ratio of these two electric fields is proportional to the ratio of the two K's: Electric field in low-K interface layer is equal to electric field in the high-K material times the K of the high-K material and divided by the K of the low-K interface layer: E₁ₙ=(K₂ₙ/K₁ₙ)E₂ₙ. This is because the normal component of the electric flux density is conserved across a boundary interface that does not hold a sheet of charge (D₁ₙ=D₂ₙ), and electric flux density is the product of K of each material multiplied by the permittivity of free space multiplied by electric field: D=Kε₀E. The high electric field in the low-K interface layer increases the band bending in the low-K interface layer, and this makes the conditions more favorable for tunneling across the interface layer. The lower E_{C} value of the high-K material as compared to that of the low-K interface layer provides available energy states for electrons coming from the cathode to elastically tunnel into these energy states of the high-K region.

The technology described herein provides for smoothly transitioning from a low-K interface layer into a high-K layer without having to subject the dielectric stack to high temperature annealing processes that may also deleteriously result in deeper transistor p-n junction, stronger short channel effects, and poly-crystallization of the high-K materials. In one embodiment the transition from low-K to high-K material is affected from the onset of the deposition of the low-K interface layer. In another embodiment, this transition is affected after some finite depth of the low-K material has already been deposited. The enhanced tunneling through a low-K/high-K barrier is maximized at a certain thickness of the low-K interface layer. Thinner or thicker interface layers typically result in less tunneling current. If the interface layer is too thin, then the band bending in the interface layer is not substantial enough to allow elastic tunneling as described earlier. If the interface layer is too thick, then the tunneling resistance of a thicker, high barrier interface layer diminishes the tunneling current. The optimal thickness of the interface layer depends on the dielectric constants of the two dielectrics, and the bottom of the conduction band values of the two dielectrics. This situation becomes somewhat more complicated to analyze with a smoothly transitioning crested-K barrier.

Yet another embodiment consists of a tunnel dielectric that is designed for tunneling in one direction only. In such a system, the tunnel dielectric may be designed only for tunneling during, for example, programming operations only. Erase may be performed by hot hole injection or by tunneling erase through a separate dielectric. In such a system. Instead of having a tri-layer system to create a crested-K barrier, only a bi-layer system is sufficient. The bi-layer system will simply consist of a low-K, high barrier interface layer adjacent the cathode, followed by a high-K, low barrier dielectric. The advantage of this system is that no potential well is formed, as it would be in a tri-layer dielectric system. Electrons tunneling into the high-K material experience only a down hill slide all the way into the anode, without encountering another high energy barrier which could lead to reflection of impinging electrons and their subsequent trapping into the high-K dielectric.

The technology described above also applies to dielectrics comprising more than 2 materials, where X is the mole fraction of the first material, Y is the mole fraction of the second material, and (1-X-Y) is the mole fraction of the third material. An example of the third material is nitrogen. The technology described herein also applies to dielectrics comprising more than 3 materials. A realistic example would be HfSiON (3 materials plus oxygen), or HfAlSiON (4 materials plus oxygen), or HfAlTaSiON (5 materials plus oxygen). In general, the technology described herein also applies to dielectrics comprising N different types of atoms, the mole fraction of any number of them being a function of depth

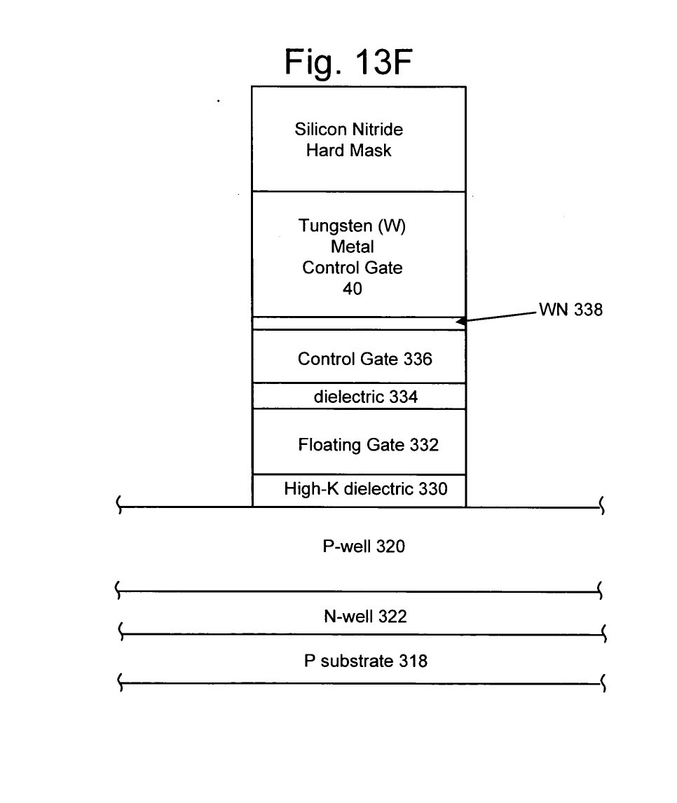

FIG. 15 is a block diagram of one embodiment of a memory system that can use flash or other non-volatile memory cells incorporating the above-described technology. Memory cell array 502 is controlled by column control circuit 504, row control circuit 506, c-source control circuit 510 and p-well control circuit 508. Column control circuit 504 is connected to the bit lines of memory cell array 502 for reading data stored in the memory cells, for determining a state of the memory cells during a program operation, and for controlling potential levels of the bit lines to promote the programming or to inhibit the programming. Row control circuit 506 is connected to the word lines to select one of the word lines, to apply read voltages, to apply program voltages and to apply an erase voltage. C-source control circuit 510 controls a common source line (labeled as “C-source” in FIG. 15) connected to the memory cells. P-well control circuit 508 controls the p-well voltage during erase operations to, for example, apply positive voltages to the P-well while the word lines of a block that is selected for an erase operation are grounded.

The data stored in the memory cells are read out by the column control circuit 504 and are output to external I/O lines via data input/output buffer 512. Program data to be stored in the memory cells are input to the data input/output buffer 512 via the external I/O lines, and transferred to the column control circuit 504. The external I/O lines are connected to controller 518.

Command data for controlling the flash memory device is input to controller 518. The command data informs the flash memory of what operation is requested. The input command is transferred to state machine 516, which controls column control circuit 504, row control circuit 506, c-source control 510, p-well control circuit 508 and data input/output buffer 512. State machine 516 can also output status data of the flash memory such as READY/BUSY or PASS/FAIL.

Controller 518 is connected or connectable with a host system such as a personal computer, a digital camera, personal digital assistant, etc. Controller 518 communicates with the host in order to receive commands from the host, receive data from the host, provide data to the host and provide status information to the host. Controller 518 converts commands from the host into command signals that can be interpreted and executed by command circuits 514, which is in communication with state machine 516. Controller 518 typically contains buffer memory for the user data being written to or read from the memory array.

One exemplar memory system comprises one integrated circuit that includes controller 518, and one or more integrated circuit chips that each contain a memory array and associated control, input/output and state machine circuits. The trend is to integrate the memory arrays and controller circuits of a system together on one or more integrated circuit chips. The memory system may be embedded as part of the host system, or may be included in a memory card (or other package) that is removably inserted into the host systems. Such a removable card may include the entire memory system (e.g. including the controller) or just the memory chip(s) and associated peripheral circuits (with the Controller being embedded in the host). Thus, the controller can be embedded in the host or included within a removable memory system.

In some implementations, some of the components of FIG. 15 can be combined. In various designs, all or some of the components of FIG. 15, other than memory cell array 502, can be thought of as control circuits or a control circuit.

In one embodiment of the present invention, NAND type flash memory cells are used. The NAND cells are arranged with multiple transistors in series between two select gates. The transistors in series and the select gates are referred to as a NAND string. The discussion herein is not limited to any particular number of memory cells in a NAND string or NAND chain. Furthermore, the present invention is not limited to NAND flash memory cells. In other embodiments flash memory cells other than NAND cells (e.g. NOR cells or other cells) can be used to implement the present invention. In yet other embodiments, non-volatile memory cells other than flash memory cells can be used to implement the present invention.

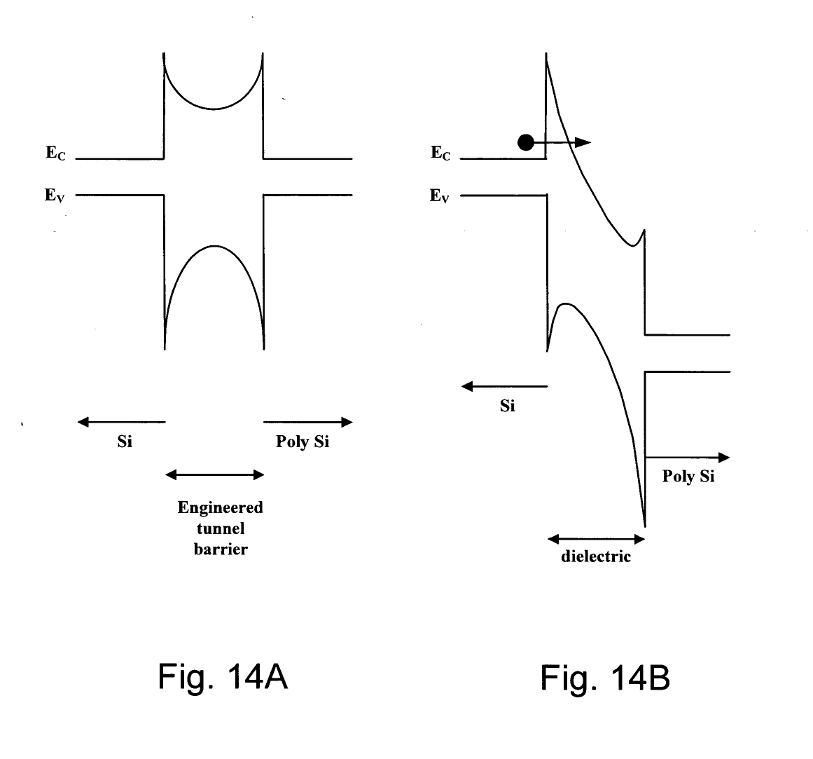

FIG. 16 depicts an example of an organization of memory cell array 502, using NAND memory cells. Memory cell array 502 is partitioned into 1,024 blocks. The data stored in each block is simultaneously erased. In one embodiment, the block is the minimum unit of cells that are simultaneously erased. In each block, in this example, there are 8,512 columns that are divided into even columns and odd columns. The bit lines are also divided into even bit lines (BLe) and odd bit lines (BLo). FIG. 16 shows four memory cells connected in series to form a NAND string. Although four cells are shown to be included in each NAND string, more or less than four memory cells can be used. One terminal of the NAND string is connected to corresponding bit line via a first select transistor SGD, and another terminal is connected to c-source via a second select transistor SGS.

During read and programming operations, 4,256 memory cells are simultaneously selected. The memory cells selected have the same word line and the same kind of bit line (e.g. even bit lines or odd bit lines). Therefore, 532 bytes of data can be read or programmed simultaneously. In one embodiment, these 532 bytes of data that are simultaneously read or programmed form a logical page. Therefore, one block can store at least eight logical pages (four word lines, each with odd and even pages). When each memory cell stores two bits of data (e.g. a multi-level cell), one block stores 16 logical pages. Other sized blocks and pages can also be used with the present invention. Additionally, architectures other than that of FIGS. 15 and 16 can also be used to implement the present invention.

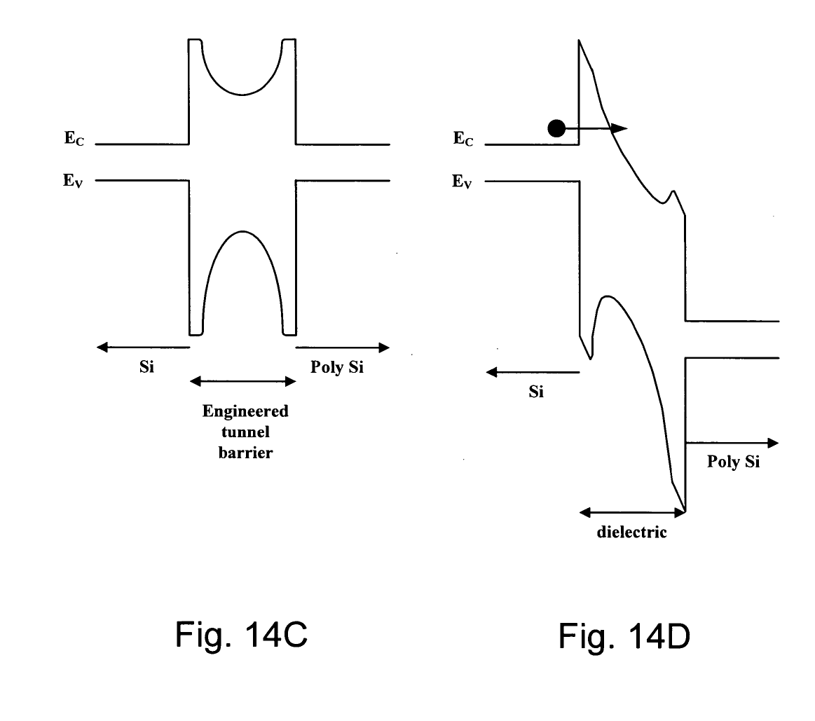

Another embodiment for creating the dielectric region of two or more materials with mole fractions varying as a function of depth is to co-inject the two materials during the ALD process. For example, the article “Ozone-Based Atomic Layer Deposition of HfO₂ and HfₓSi₁₋ₓO₂ and Film Characterization,” Senzaki, Park, Tweet, Conley and Onon, Mat. Res. Soc. Symp. Proc. Vol. 811, 2004 describes co-injecting two precursors during an ALD process. FIG. 17 is a flow chart describing one embodiment for an ALD process that includes co-injection. In step 602, two precursors are co-injected into the chamber. In step 604, the chamber is purged. In step 606, an oxidizing agent is introduced into the chamber. In step 608, the chamber is purged. For example, alternating pulses of Hf/Si precursor vapor mixture and ozone allow for the growth of HfₓSi₁₋ₓO₂ films. The process of FIG. 17 can be used as part of step 160 of FIG. 5, with the amount of the Hf and Si precursors changing as a function of depth in the dielectric region in order to achieve a crested bottom of a conduction band profile for the dielectric region.

Some high-k dielectrics can suffer from increased trapping, and poly-crystallization at lower temperatures. It has been found that film quality can be increased through introduction of nitrogen in high-K materials such as hafnium oxide, hafnium silicate, zirconium oxide, hafnium tantalum oxide, etc. Sufficient quantities of nitrogen can be more easily incorporated into these films by in-situ nitridation and/or by forming nitrides in-situ and then oxidizing these nitrides in-situ to form oxy-nitrides. Ammonia gas, nitrogen gas in presence of plasma, and/or in-situ or remotely generated radical nitrogen can be used for the nitridation of metal species. Any of these species (or others) can be referred to as nitriding agent. Water, ozone, in-situ or remotely generated radical oxygen can be used for oxidation. Any of these species or others) can be referred to as oxidizing agent. Both oxidizing or nitriding agents can be delivered in lower concentrations by mixing them with inert gases such as molecular nitrogen, or inert gases such as He, Ne, Ar, Kr, Xe, Rn. The hydrogen in any of these agents, such as ammonia or water can be replaced with the hydrogen isotope, deuterium.

A new complex ALD cycle is proposed here where after the deposition of the metal(s) precursors, and the purge of metal precursor(s), a nitridation step is performed followed by, or concurrently with, an oxidation step. For example, the nitridation and oxidation step can include first exposing the substrate surface to the nitriding agent, then purging this agent, and subsequently exposing the wafer to oxidizing agent and then purging the oxidizing agent. Alternatively, both the nitriding, and oxidizing agents can be simultaneously released into the chamber at appropriate ratios, and later purged. Another alternative is to first release the nitriding agent, shortly thereafter release the oxidizing agent, and finally purge the mixture. Yet another sequence is to first release the nitriding agent, followed by release of the oxidizing agent, and then followed by another release of the nitriding agent, all followed by a single purge. If multiple nitriding or oxidizing pulses are applied, the chemistries of each pulse can be different from the next pulse. The above processes can be performed within a single ALD cycle and across multiple ALD cycles. As the dielectric is being created at a rate one or sub-one atomic layer per cycle, the chemistries and exposure times and sequences can be varied to create a varying nitrogen and oxygen concentration as a function of depth.

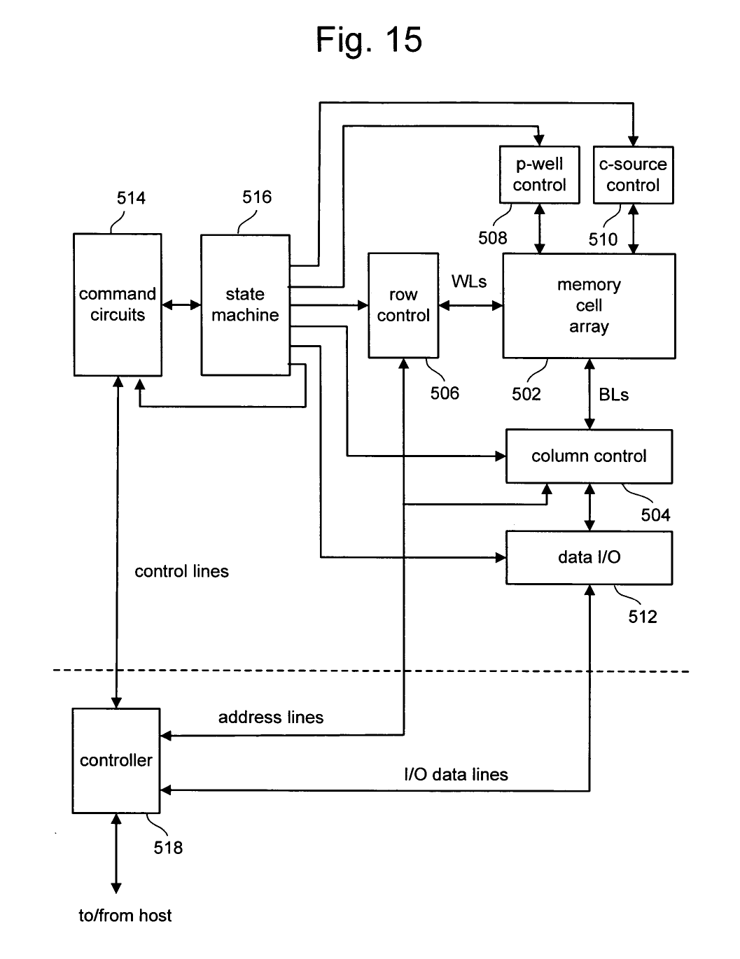

FIG. 18 is a flow chart describing one embodiment for performing the ALD cycle that includes the nitridation and oxidation steps. In step 622, two or more precursors are co-injected into the chamber, with the substrate in the chamber. In step 624, the chamber is purged. In step 626, the one or more nitriding agents and one or more oxidizing agent(s) are co-injected into the chamber. In step 628, the chamber is purged. In various alternatives, the chamber can be purged at intermittent points during step 626.

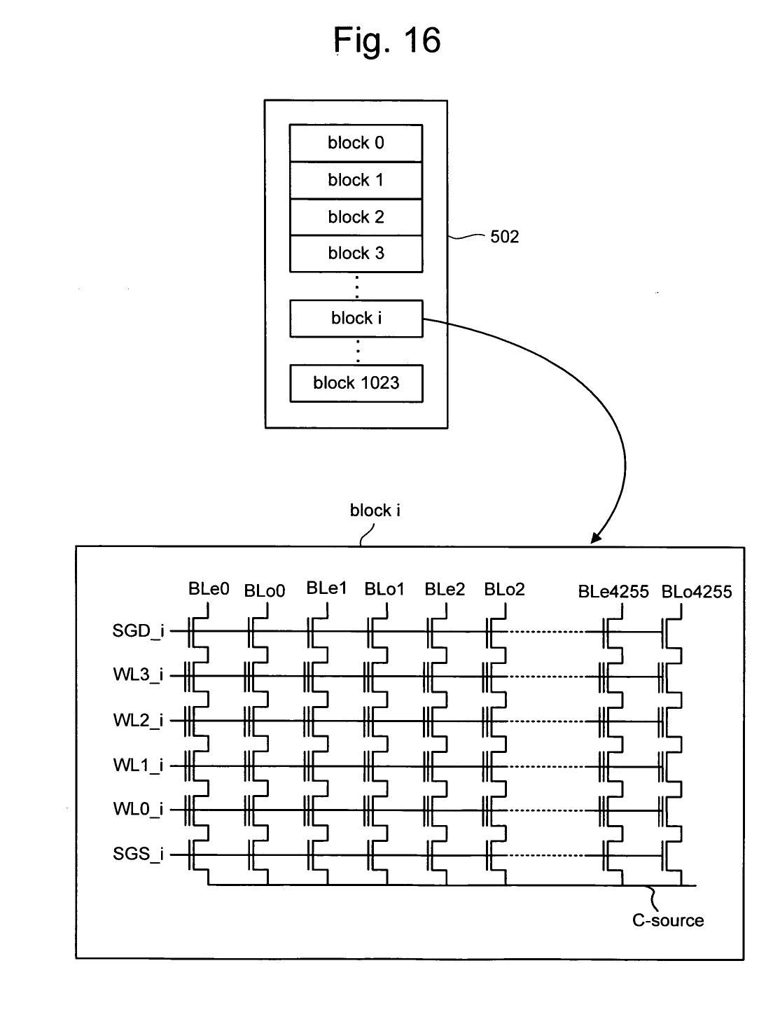

There are various options for co-injecting the nitriding agent(s) and the oxidizing agent(s) (step 626). Three suitable options are depicted in FIGS. 19A, B and C. The graphs plot flow rate versus time. In some embodiments, the nitriding pulses have a higher flow rate and therefore concentration of nitriding agent(s) than the concentration of oxidizing agent(s) in oxidizing pulses.

FIG. 19A shows a pulse 650 of one or more nitriding agent from times to t₀ time t₁, followed by a pulse 652 of one or more oxidizing agent from time t₂ to time t₃, followed by another pulse 654 of one or more nitriding agents from time t₄ to time t₅. Purging can happen between pulses and/or after the last pulse. Additionally, more pulses can be used. Pulse 652 is provided for less time and at a lower flow rate/concentration than pulses 650 and 654. In other embodiments, pulse 652 can be at a similar flow rate/concentration or similar amount of time as pulses 650 and 654. The two nitriding pulses 650 and 654 can be performed using the same nitriding agent(s) or different nitriding agents.

FIG. 19B shows a pulse 660 of one or more nitriding agents from time tₐ to time t_{d}. A pulse 662 of one or more oxidizing agents is provided from time t_{b} to time t_{c}. Pulse 662 is provided concurrently with pulse 660, but for less time and at a lower concentration.

FIG. 19C shows a pulse 670 of one or more nitriding agents from time tⱼ to time tₖ. After time tₖ, pulse 672 of one or more oxidizing agents is provided from time tₗ to time tₘ. Pulse 672 is provided after pulse 670, for less time and at a lower concentration.

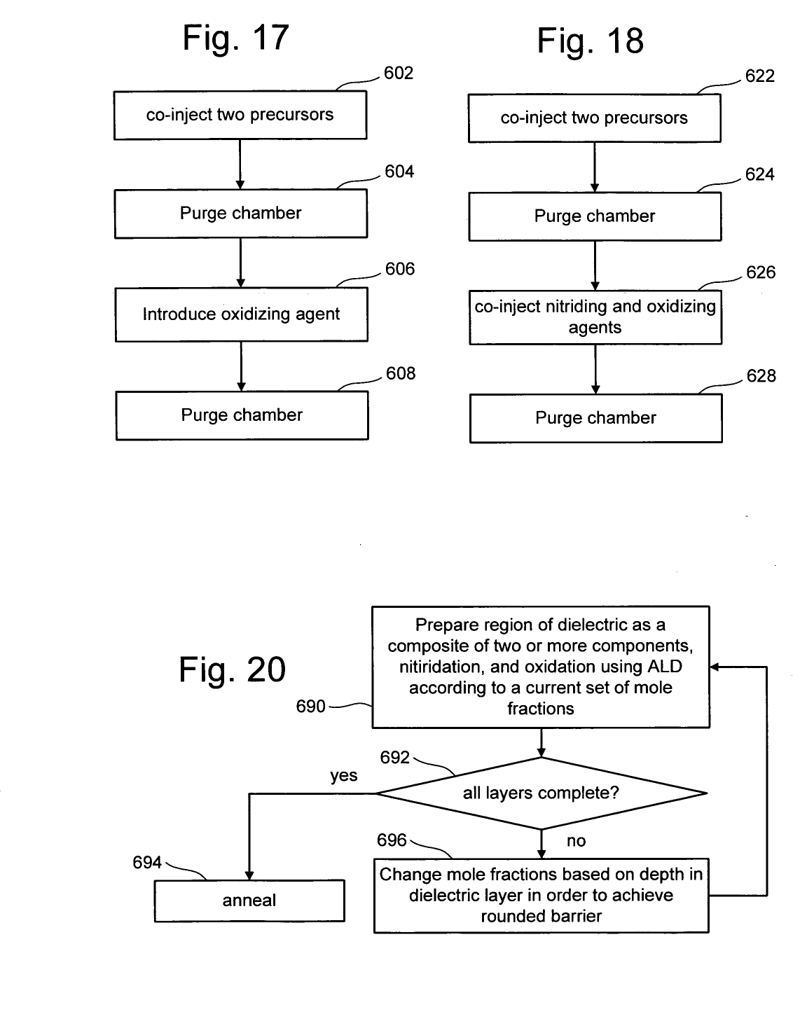

The process of FIG. 18 can be repeated, while varying the mole fractions of either the precursors of step 622 and/or the nitriding/oxidizing agents of step 626 as a function of ALD cycle number which will correspond to varying the mole fractions of various species as a function of depth in the dielectric layer as the dielectric is being deposited layer by layer. For example, the timing and/or flow rate of the pulses of the nitriding/oxidizing agents of steps 626 can be varied. This concept is depicted in the flow chart of FIG. 20. In step 690, a region of the dielectric is made using two or more precursors, a nitridation step and an oxidation step, as per the process of FIG. 18. If all of the regions of the dielectric have been added (step 692), then the dielectric is annealed in step 694. Some embodiments do not require an annealing operation. If all regions have not been added, then in step 696 the mole fractions of the two metals of step 622 and/or of the oxygen and nitrogen of step 626 are varied to achieve a rounded/crested barrier.

In one example of depositing a uniform hafnium silicon oxy-nitride film, each ALD cycle will start with the co-injection of the metal precursors TEMMAHf (tetrakis-ethylmethylamino hafnium) and TEMMASi (tetrakis-ethylmethylamino Silicon) at proper ratios to produce the desired concentrations of Hf and Si in the film. This is followed by purge of these precursor gases. Then a nitridation step using ammonia is employed, and this is followed by an oxidation step by releasing ozone in the ALD chamber. The ammonia and ozone gas are then purged in a single purge operation. The amounts of gas, the durations of exposure to each gas, and the delay between the release of ammonia and the subsequent release of ozone have to be tuned to achieve the desired incorporation levels of nitrogen/oxygen in the dielectric film.

It is known that the bonding energy of oxygen to most metals and to most semiconductors is greater than the bonding energy of nitrogen to the same. Therefore, in order to incorporate sufficient concentrations of nitrogen into high-K dielectric films, it may be beneficial to oxidize an already nitrided film rather than to nitride and already oxidized film. Oxidation of a nitrided film may create a film with fewer metal-to-metal or metal-to-silicon bonds, and/or fewer dangling bonds.

Another approach can include N cycles of HfSiN deposition followed by exposure to oxidizing agent, where N is an integer number greater than or equal to 1. This would allow the oxidation of HfSiN before the film becomes too thick for the underlying layers to be oxidized by reasonable exposure times and temperatures to oxidizing agent(s).

Silicon oxy-nitride with higher nitrogen concentrations can be ALD deposited by using the above method of first nitriding silicon and then oxidizing the silicon nitride. Another example of a suitable material is HfSiTaON.

When performing an ALD process, oxygen radicals may react more readily with a metal during the oxidation stage than regular oxygen. The reason for this is that for the case of radical oxygen no initial energy barrier associated with breaking the bond between the oxygen and whatever atom(s) it is bound to (for example another oxygen atom it may be bound to) needs to be surmounted. This means that radical oxygen will react more readily with metal or semi-conductor atoms and the energy released will be larger, translating into faster reaction rates and oxidation of more metal or semiconductor atoms. The quality of dielectric film depends on minimizing metal/semiconductor to metal/semiconductor bonds by making sure that all metal/semiconductor atoms are bonding to oxygen or nitrogen, and not to another metal atom. Metal/semiconductor to metal/semiconductor bonds can result in current leakage paths in dielectric materials. Examples of metal/semiconductor to metal/semiconductor bonds include Hf to Si bonds, Hf to Hf bonds, and Si to Si bonds. Radical oxygen with its stronger reactivity to metals can reduce the number of metal to metal bonds in dielectrics. Thus, in one embodiment, a high-density plasma is used to form oxygen radicals that serve as the oxidizing agent for ALD. Oxygen radicals and inert gas ions can be formed by first introducing an oxygen containing feed gas (radical generating feed gas) and an inert gas containing feed gas (ion generating feed gas) into a plasma chamber. The gases can be excited by a microwave source, for example, to produce oxygen radicals and other gas ions (Note: ions are not inert). After the radicals and ions are produced, they can be introduced to the deposition chamber to react with the first precursor at the substrate surface to form the desired oxide or oxynitride material.

In one embodiment, krypton is used as the ion generating feed gas. The meta-stable states of krypton have greater capability to selectively dissociate oxygen into oxygen radicals. Krypton shows greater efficiency in dissociating oxygen into highly reactive oxygen radicals rather than less reactive oxygen ions when compared with other inert gases.

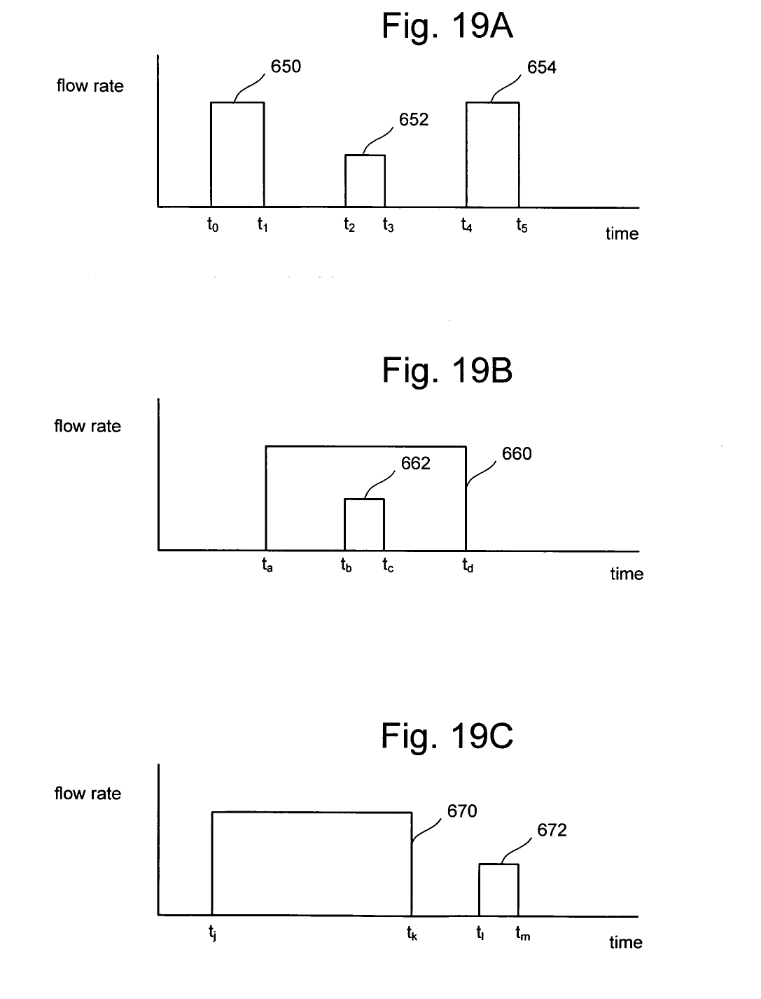

FIG. 21 is a generalized block diagram of an ALD system 700 in accordance with one embodiment. Other systems known in the art can also be used, including those systems that do not use krypton and/or that do not use oxygen radicals. ALD system 700 includes a deposition chamber 702 that can house one or more substrate wafers upon which one or more films are to be deposited. Chamber 702 includes a wafer chuck 704 for supporting and maintaining one or more wafers 708 during the deposition process. Wafer chuck 704 is coupled to a wafer heating element 706 to maintain the substrate at a suitable temperature for deposition thereon. In one embodiment, the ALD process temperature is in the range of about 250° to 350° C., although any suitable ALD process temperature can be used in accordance with desired implementations.

In one embodiment, chuck 704 is coupled to a voltage bias that can electrostatically hold substrate wafer 708 to the chuck. Other means for maintaining the wafer in position can be used in various embodiments. Container 712 holds the first precursor which can be delivered uniformly over substrate wafer 708 through showerhead 714. In some embodiments, container 712 can include multiple containers to store multiple first precursors. A second container 738 can be provided to hold a second first precursor if so desired for a particular implementation.

Between precursor pulses and/or after introduction of inert gas into the chamber, excess reactant and by-products can be removed from the chamber through one or more valves 716 utilizing some pump(s) that are not shown in FIG. 21. In one embodiment, system 700 can be formed in a substantially circular shape, having a circular chuck 704 surrounded by one or more valve(s) 716.

System 700 further includes a plasma source chamber 720 for the generation of radicals that can serve as the second precursor (reactant) in the deposition process. A first feed gas such as Ar, Xe, Kr, He, N₂ etc. can be delivered into chamber 720 from container 722 while a second feed gas such as H₂O, H₂, O₂, or O₃ can be delivered from container 724.

One or more microwave energy sources 726 or other suitable energy source (e.g., a radio frequency energy source) provide energy to the chamber through a horn antenna, waveguide, or other mechanism 728 to excite the feed gases and generate the high-density plasma. A dielectric barrier 730 that is impermeable to gases but permeable to microwaves (or RF waves if such an energy source is used) is provided between the energy source and gas mixture. In one embodiment, dielectric barrier 730 is quartz. In one embodiment, dielectric barrier 730 is preferably a material that will not oxidize or nitridize, etc. in the presence of oxygen or nitrogen radicals. Microwave energy source 726 excites the feed gases, forming a high-density mixed plasma in chamber 720. A mixture of an inert feed gas and an oxygen, hydrogen, nitrogen, or other desired reactant carrying second feed gas (e.g., molecular oxygen, O₂) can be provided into the plasma source chamber. Microwave energy source 726 can excite the inert gas and second feed gas to form radicals that can serve as the second reactant in the deposition process. For example, an inert gas and oxygen bearing gas can be provided to the chamber and excited to generate oxygen radicals (O1D). Ions will also be generated from the first feed gas. These ions can impact the substrate along with the generated radicals to drive surface reactions between the first precursor and radicals (second precursor or reactant).

A plurality of valves 736 are provided in a separation layer 740 between the two chambers. The valves can be opened to deliver the radicals and ions to the substrate at the appropriate time during the deposition process. Any number of means for selectively delivering the radicals and ions from the plasma source chamber to the deposition chamber can be used in accordance with various embodiments. The valves as illustrated in FIG. 21 include a ferromagnetic inner material surrounded by solenoid coils to form an electromagnetic valve. A voltage can be applied to the coils of the electromagnetic to force the ferromagnetic material upward, thus opening the valve. In one embodiment, the high-density mixed plasma can be generated continuously and selectively applied to the substrate by opening and closing valves 736. In other embodiments, plasma generation can be toggled on and off during the process using energy source 726 and/or valves 732 and 734 that regulate the delivery of feed gases to plasma chamber 726.

Note that FIG. 21 depicts solenoid type valves that are electromechanically operated. Other embodiments employ a single valve for a given gas or a given gas mixture. However, the cycle times may need to be extended to make sure that the pipes extending from the valves to the chamber(s) are sufficiently purged. Other types of valves can also be used.

Purge operations can be done by employing vacuum pumps to remove gases from chambers (negative pressure), by injecting chemically inert purge gases into the chamber (positive pressure) that would remove the existing gases through orifices located at opposite side of the chamber, or by employing both positive pressure from injecting inert gas and simultaneous negative pressure by utilizing vacuum pumps.

In one embodiment, showerhead 714 is formed of a mesh material that allows materials delivered from plasma source chamber 720 to reach the substrate surface. In other embodiments, showerhead 714 can be moveable such that is placed above the substrate to introduce the first precursor and then moved out of the way to allow the second precursor to be delivered from plasma source chamber 702.

In one embodiment, krypton (Kr) is preferably used as an inert gas for the generation of oxygen and/or nitrogen radicals in a high-density mixed plasma to deposit one or more oxide, nitride, or oxynitride containing layers. A dielectric, e.g. aluminum oxide, silicon oxide, or hafnium oxide, hafnium silicate, or hafnium silicon oxynitride can be deposited with very high density using a Kr and oxygen carrying feed gas (e.g., O₂) mixture, thus resulting in a robust, high quality oxide. For example, silicon oxides deposited from a Kr/O₂ plasma can maintain a good O/Si mixture and have a low interface trap density that is comparable to or less than thermally grown silicon oxide.

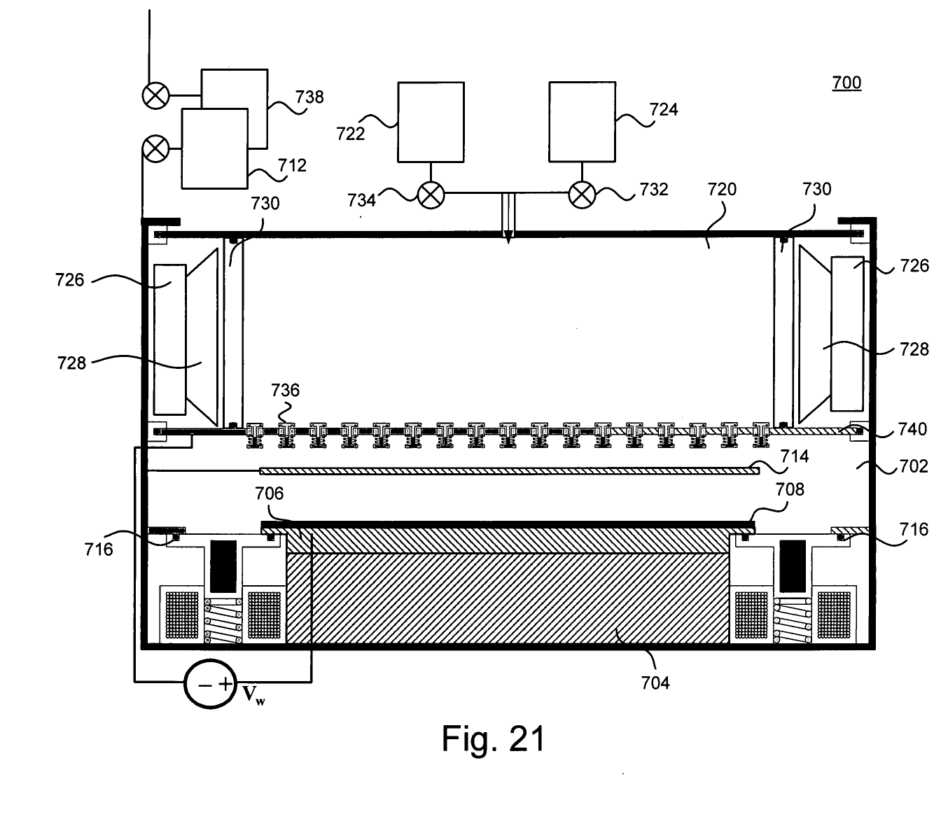

Kr shows improved benefits over other inert gases for the production of oxygen radicals in a high-density mixed plasma. FIG. 22 is an energy diagram illustrating various dissociation energies of oxygen and the metastable states of various inert gases. The dissociation energy of molecular oxygen, O₂, into two oxygen radicals (O¹D+O¹D) is approximately 11.6 eV, while the dissociation energy of molecular oxygen into a molecular oxygen ion, O₂⁺, is 12.1 eV. The first metastable state of Ar is 11.6 eV, which is closest to the dissociation energy for oxygen radicals (O¹D+O¹D) of the four inert gases. Thus, oxygen radicals (O¹D+O¹D) can be generated from the first metastable state of Ar. Because the energy state (12.1 eV) of a molecular oxygen ion (O₂⁺) is close to the dissociation energy of oxygen to oxygen radicals (O¹D+O¹D=11.6 eV), however, molecular oxygen ions can be excited by the second or higher metastable state of Ar. This results in the inefficient generation of oxygen radicals in an Ar/O2 mixed plasma. The resulting plasma will generate a large concentration of molecular oxygen ions in addition to the oxygen radicals. Molecular oxygen ions have a lower oxidation force which leads to slower deposition of oxides and oxides of a poorer quality. Assisted by the bombardment of inert gas ions, the deposition rate from oxygen radicals is greater than that from oxygen molecules because of the higher reaction rate of oxygen radicals with Si or with other metal precursors.

The first metastable state of Kr is second closest to the dissociation energy of molecular oxygen into oxygen radicals and can be used to generate oxygen radicals from molecular oxygen. The second or higher metastable states of Kr, unlike Ar, are unable to excite molecular oxygen ions. Therefore, oxygen radicals can be selectively generated in Kr high-density plasma to produce a large concentration of oxygen radicals without also providing a large number of oxygen ions. This results in the deposition of oxide films having very good properties and deposition times. The resulting oxides should have low leakage currents, good breakdown field intensity, good charge to breakdown distribution, good stress-induced leakage current, low interface trap charge, and low bulk charge.

Inert gases such as Kr can also be used to deposit very high quality oxynitride films having similar benefits to those set forth above. For example, microwave excited high density Kr/O₂/NH₃ plasma can be used to deposit a silicon oxynitride film. By using Kr, the improvements over other inert gases as discussed above can be achieved in various embodiments. Nitride films can also be deposited using Kr or other inert gases.

Improved high-K dielectrics can be deposit by utilizing plasma generated oxygen and/or nitrogen radicals to improve the quality of the high-K dielectric through suppression of defect and trap sites. This is achieved by a more complete oxidation and/or nitridation process which is provided by the stronger reactivity of free radicals. Another benefit or sometimes a side effect of employing radicals is to grow thicker interface layers which are typically of lower K. For example, as HfSiON is being deposited on the top surface of a substrate, some free radical of oxygen and/or nitrogen will more readily diffuse through the high-K HfSiON layers and the existing interfacial layer and react with the silicon surface residing below the dielectrics to form silicon oxide, or silicon oxynitride. The interface layer will not be pure oxide or oxynitride, but will also contain some amounts of Hf. The quality of this grown lower-K, but higher band gap interface layer will be very good with low trap sites. This reduces the density of interface traps and shallow oxide traps, and provides a benefit ion terms of higher electron/hole mobility and lower noise and hysteresis. However, the low-K interface layer can increase leakage currents due to increased tunneling through the lower K interface layer when the electrode adjacent the interface layer is the cathode for electron injection. There is a higher field in the low-K interface layer since the K is lower in this layer. This can be an undesirable effect unless it is intentionally taken advantage of in devices where the objective is to increase the tunneling current.

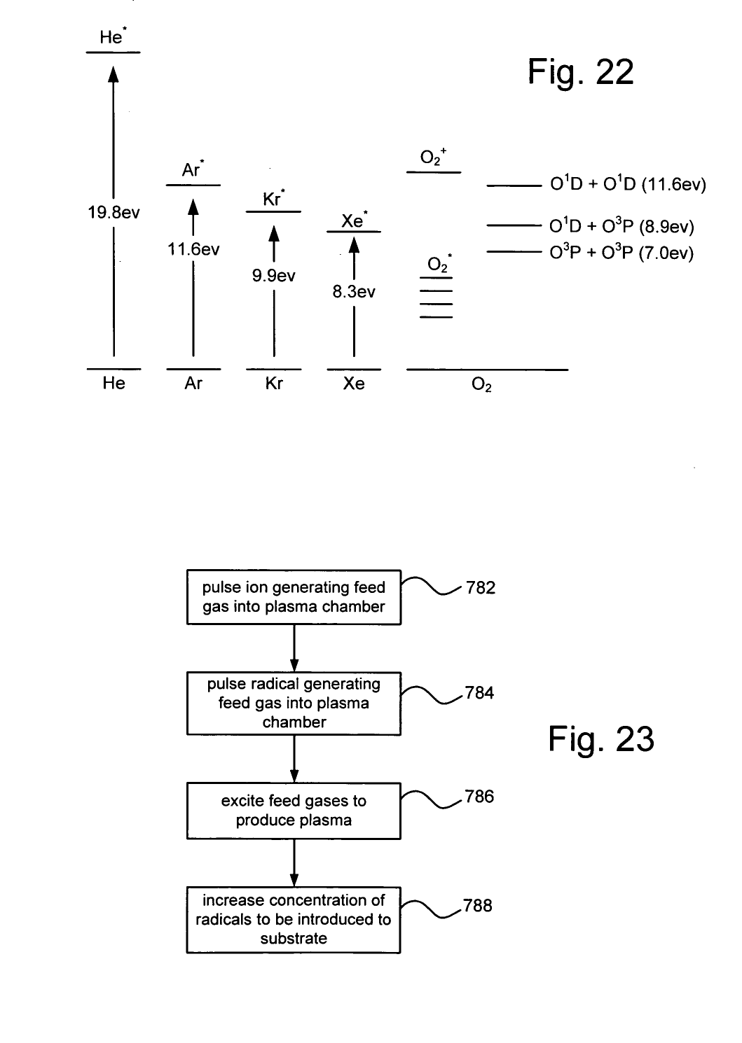

In accordance with various embodiments, one or more techniques can be used to increase the radical concentration delivered to the substrate surface in order to increase the efficiency and quality of a deposited material such as an oxide from oxygen radicals. FIG. 23 is a flowchart of one embodiment for performing an ALD process while increasing a concentration of radicals delivered to the substrate as a second precursor or reactant.

The process of FIG. 23 is performed after the first precursor (or set of precursors) is introduced into deposition chamber 702 to form a monolayer on the wafer surface. In steps 782 and 784, an ion generating feed gas and a radical generating feed gas are introduced into plasma source chamber 720. The two feed gases are excited from a microwave or other suitable energy source at step 786 to generate a plasma-containing radicals and ions formed from the feed gases. For example, a Kr ion generating feed gas and oxygen radical generating feed gas can be used to form Kr ions and oxygen radicals.

Because the concentration of oxygen radicals (relative to molecular oxygen ions and molecular oxygen) affects the quality, efficiency, and rate of deposition of an oxide material it is desirable to increase the concentration of oxygen radicals relative to these other materials. The higher reactivity of free radicals may afford shorter pulse widths for the precursor 2. This can have a positive impact on the over all deposition rate. Accordingly, at step 788, one or more techniques are employed to increase the concentration of radicals relative to other materials that are delivered to the deposition chamber and ultimately the wafer from plasma source chamber 720. For example, an additional energy source can be included in the plasma source chamber to aid in the dissociation of molecular oxygen and oxygen ions into oxygen radicals. Additionally or alternatively, a bias can be applied in the deposition chamber to attract oxygen radicals to the wafer and/or to repel other less desirable materials from the wafer. In one embodiment, step 710 includes applying a bias in the plasma source chamber to attract less desirable charged ions such as oxygen ions away from the deposition chamber. Still yet in other embodiments, a selectively permeable membrane can be included in deposition system 700 to filter less desirable components and thereby increase the radical concentration. Additionally, step 788 can also include increasing the radical concentration in the plasma generated in plasma source chamber 720 and/or increasing the radical concentration after a mixture of radicals, ions, and less desirable components are introduced into the deposition chamber. Accordingly, in one embodiment step 788 is followed by the introduction of radicals and ions into deposition chamber 702 by opening valves 716. In other embodiments, step 788 is preceded by the introduction of radicals and ions into deposition chamber 702.

The ion generating feed gas and radical generating feed gas need not be pulsed into the plasma chamber. In one embodiment, they can be continuously co-injected into the plasma chamber at the same rate as these gases leave the plasma chamber so as to maintain the plasma chamber average pressure over time scales spanning multiple cycles. In one embodiment, the sequence in which these gases are fed into the plasma chamber is not of much consequence so long as the proper partial pressures are maintained over long period of time. The sequence of release of various gases into the ALD chamber, however, has direct bearing on the type, quality, and deposition rate of the ALD films to be deposited. In some embodiment, steps from 782 to 788 can take place concurrently, or in another order. In some embodiments, it is not a serial step-by-step process.

Although embodiments are discussed above that use a high-density plasma to form oxygen radicals that serve as the oxidizing agent for ALD, other more traditional ALD processes can also be used.

In some embodiments, if exposure to oxidizing agent replaces the exiting nitrogen in the dielectric with oxygen, then it may become necessary to follow several cycles of pure nitridation of metal precursor with one control and possibly limited exposure cycle of oxidation in order to achieve the proper levels of nitridation in the films, as the nitrogen in the underlying layers may be more securely bonded to the metal atoms by virtue of having one or more atomic layers of the deposited materials over it. This may provide an undesired cyclic variation in the nitrogen and oxygen mole fraction as a function of depth. However an anneal operation with a proper temperature and duration may help to homogenize this variation on the scale of a few atomic layers without obliterating the desired concentration gradients that may be intended over larger length scales along the depth of the dielectric.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

I claim:

1. A method for creating a dielectric, comprising:
(a) introducing a first precursor into a chamber having said substrate in said chamber;
(b) purging said chamber;
(c) introducing a nitriding agent into said chamber after said purging;
(d) introducing an oxidizing agent into said chamber, said introducing said oxidizing agent is started after starting said introducing said nitriding agent; and
(e) purging said chamber.

2. A method according to claim 1, wherein:
said nitriding agent is introduced at a higher concentration than said oxidizing agent.

3. A method according to claim 1, wherein:
said introducing an oxidizing agent is completed prior to completing said introducing a nitriding agent.

4. A method according to claim 1, wherein:
said introducing an oxidizing agent is started subsequent to completing said introducing a nitriding agent.

5. A method according to claim 1, wherein:
step (a) includes co-injecting said first precursor and a second precursor.

6. A method according to claim 5, wherein:
a resultant substance is created as a result of said steps (a)-(e);
said resultant substance includes a first component and a second component;
said first component is based on said first precursor;
said second component is based on said second precursor; and
said steps (a)-(e) are repeated for multiple iterations, each iteration includes varying said first precursor and said second precursor so that said first component and said second component having varying mole fractions as a function of depth in said dielectric region in order to create a crested bottom of a conduction band profile for said dielectric region.

7. A method according to claim 6, wherein:
said first component includes Hf; and
said second component includes Si.

8. A method according to claim 1, wherein:
a resultant substance is created as a result of said steps (a)-(e);
said resultant substance includes an oxygen component and a nitrogen component; and
said steps (a)-(e) are repeated for multiple iterations, each iteration includes varying steps (c) and (d) so that said oxygen component and said nitrogen component having varying mole fractions as a function of depth in said dielectric region.

9. A method according to claim 1, further comprising:
providing a substrate, said steps (a)-(e) add said dielectric to said substrate;
adding a floating gate structure on said dielectric region;
adding a second dielectric adjacent said floating gate; and
adding a control gate adjacent to said second dielectric.

10. A method according to claim 1, wherein:
step (a) includes co-injecting said first precursor and a second precursor;
said first precursor includes Hf;
said second precursor includes Si; and
HfSiON is created as a result of said steps (a)-(e).

11. A method according to claim 1, wherein:
said dielectric region created by steps (a)-(e) is a high-K dielectric region.

12. A method for creating a dielectric on a substrate, comprising:
(a) introducing a first precursor into a chamber having said substrate in said chamber, said first precursor includes a first component;
(b) introducing one or more nitriding agents into said chamber after said introducing said first precursor, said introducing said one or more nitriding agents is performed for a first time period; and
(c) introducing one or more oxidizing agents into said chamber, said introducing said one or more oxidizing agents is performed for a second time period, said second time period is shorter than said first time period.

13. A method according to claim 12, wherein:
step (a) includes co-injecting said first precursor and a second precursor into said chamber.

14. A method according to claim 12, wherein:
said nitriding agents are introduced at a higher concentration than said oxidizing agents.

15. A method according to claim 12, wherein:
said second time period at least partially overlaps with said first time period.

16. A method according to claim 15, wherein:
said second time period starts after said first time period starts; and
said second time period ends before said first time period ends.

17. A method according to claim 12, wherein:
said second time period starts after said first time period ends.

18. A method according to claim 17, further comprising:
introducing one or more nitriding agents into said chamber during a third time period after said second time period.

19. A method according to claim 12, wherein:
a resultant substance is created as a result of said steps (a)-(c);
said step (a) includes introducing a second precursor into said chamber, said second precursor includes a second component;
said resultant substance includes said first component and said second component; and
said steps (a)-(c) are repeated for multiple iterations, each iteration includes varying said first precursor and said second precursor so that said first component and said second component having varying mole fractions as a function of depth in said dielectric in order to create a crested bottom of a conduction band profile for said dielectric.

20. A method according to claim 19, wherein:
said first component includes Hf; and
said second component includes Si.

21. A method according to claim 12, wherein:
a resultant substance is created as a result of said steps (a)-(c);
said resultant substance includes an oxygen component and a nitrogen component; and
said steps (a)-(c) are repeated for multiple iterations, each iteration includes varying steps (b) and (c) so that said oxygen component and said nitrogen component having varying mole fractions as a function of depth in said dielectric region.

22. A method according to claim 12, further comprising:
purging said chamber after step (a).

23. A method according to claim 12, further comprising:
purging said chamber after step (c).

24. A method according to claim 23, further comprising:
purging said chamber after step (a).

25. A method for creating a dielectric, comprising:
co-injecting two materials into a chamber having a substrate in said chamber;
purging said chamber;
co-injecting one or more nitriding agents and an oxidizing agent into said chamber after said purging, said co-injecting includes injecting said one or more nitriding agents longer than injecting said oxidizing agent.

26. A method according to claim 25, further comprising:
purging said chamber after said co-injecting two materials.

27. A method according to claim 25, further comprising:
purging said chamber after said co-injecting one or more nitriding agents and an oxidizing agent.

28. A method according to claim 27, further comprising:
purging said chamber after said co-injecting two materials.

29. A method according to claim 25, wherein:
said nitriding agents are introduced at a higher concentration than said oxidizing agents.

30. A method according to claim 25, wherein:
said co-injecting two materials is repeated with iterations that vary mole fractions of said two materials as a function of depth in said dielectric region in order to create a crested bottom of a conduction band profile for said dielectric region.

31. A method according to claim 25, wherein:
said co-injecting one or more nitriding agents and an oxidizing agent is repeated with iterations that vary mole fractions of said one or more nitriding agents and said oxidizing agent as a function of depth in said dielectric region.

32. A method according to claim 25, wherein said co-injecting one or more nitriding agents and an oxidizing agent comprises:
injecting said one or more nitriding agents; and
injecting said oxidizing agent subsequent to completing said injecting said one or more nitriding agents.

33. A method according to claim 25, wherein said co-injecting one or more nitriding agents and an oxidizing agent comprises:
injecting said one or more nitriding agents; and
injecting said oxidizing agent while injecting said one or more nitriding agents.

34. A method according to claim 25, wherein said co-injecting one or more nitriding agents and an oxidizing agent comprises:
performing a first injection of said one or more nitriding agents;
injecting said oxidizing agent subsequent completing said first injection of said one or more nitriding agents; and
performing a second injection of said one or more nitriding agents after injecting said oxidizing agent.

35. A method for creating a dielectric, comprising:
(a) introducing a first precursor into a chamber having said substrate in said chamber, said first precursor includes at least a first material;
(b) purging said chamber after introducing said first precursor;
(c) performing a nitridation process in said chamber after said purging said chamber after introducing said first precursor;
(d) performing an oxidation process in said chamber, said oxidation process is performed at a lower concentration than said nitridation process; and
(e) purging said chamber.

36. A method according to claim 35, wherein:
step (a) includes co-injecting a first precursor and a second precursor;

37. A method according to claim 36, wherein:
a resultant substance is created as a result of said steps (a)-(e);
said resultant substance includes a first component based on said first precursor and a second component based on said second precursor; and
said steps (a)-(e) are repeated for multiple iterations, each iteration includes varying said first precursor and said second precursor so that said first component and said second component having varying mole fractions as a function of depth in said dielectric region in order to create a crested bottom of a conduction band profile for said dielectric region.

38. A method according to claim 35, wherein:
a resultant substance is created as a result of said steps (a)-(e);
said resultant substance includes an oxygen component and a nitrogen component; and
said steps (a)-(e) are repeated for multiple iterations, each iteration includes varying steps (c) and (d) so that said oxygen component and said nitrogen component having varying mole fractions as a function of depth in said dielectric region.
